(19) United States
(12) Patent Application Publication
(10) Pub. No.: US 2026/0277063 A1
(43) Pub. Date: Sep. 17, 2026

(54) ARRAY SUBSTRATE AND PREPARATION METHOD THEREOF, DISPLAY PANEL, AND DISPLAY DEVICE

(71) Applicants: Beijing BOE Technology Development Co., Ltd., Beijing (CN); BOE Technology Group Co., Ltd., Beijing (CN)

(72) Inventors: Jianyun XIE, Beijing (CN); Wenwen QIN, Beijing (CN); Xiaoxiang ZHANG, Beijing (CN); Ning WANG, Beijing (CN); Jian SUN, Beijing (CN); Yezhou FANG, Beijing (CN); Baoman LI, Beijing (CN)

(21) Appl. No.: 18/870,025

(22) PCT Filed: Oct. 17, 2023
(86) PCT No.: PCT/CN2023/124967

§ 371 Date: Nov. 27, 2024

(51) Int. Cl. G02F 1/1362; G02F 1/1333; G02F 1/1343; G02F 1/1368; H10D 86/01; H10D 86/40

(52) U.S. Cl. CPC G02F 1/136209; G02F 1/133357; G02F 1/13439; G02F 1/136222; G02F 1/1368; H10D 86/0231; H10D 86/441; H10D 86/451

(57) ABSTRACT

An array substrate and a preparation method thereof, a display panel, and a display device. The array substrate includes a first base substrate; a group of thin film transistors; the thin film transistor including a gate electrode, a source electrode, and a drain electrode; a planarization layer, including first through holes in a one-to-one correspondence with the thin film transistors; the first through hole exposing some region of a surface of the drain electrode facing away from the first base substrate; a group of first electrodes; the first electrodes being connected to the drain electrodes through the first through holes; a group of first filling portions; a group of second electrodes, on a side of the first electrodes and a side of the first filling portions facing away from the first base substrate.

### CROSS REFERENCE TO RELATED APPLICATION

The present disclosure is a national phase entry under 35 U.S.C § 371 of International Application No. PCT/CN2023/124967, filed on Oct. 17, 2023. The entire content of which is incorporated in the present disclosure by reference.

### TECHNICAL FIELD

The disclosure relates to the field of display technology, in particular to an array substrate and a preparation method thereof, a display panel and a display device.

### BACKGROUND

Liquid crystal display devices are widely used in modern information equipment because of their advantages, such as light weight and low power consumption, etc.

A sub-pixel of the liquid crystal display device includes a thin film transistor and a pixel electrode. A planarization layer is provided between the thin film transistor and the pixel electrode. The pixel electrode is electrically connected to the thin film transistor through a through hole penetrating through the planarization layer. However, the presence of the through hole of the planarization layer causes liquid crystal disorder in the through hole and a region surrounding the through hole, which leads to a light leakage problem, therefore, a light-shielding pattern needs to shield the through hole and the region surrounding the through hole, i.e., the region of the liquid crystal disorder, and a size of the light-shielding pattern is large, which affects the aperture ratio of the sub-pixel.

### SUMMARY

Embodiments of the disclosure provide an array substrate, including:
a first base substrate;
a plurality of thin film transistors, on a side of the first base substrate; each of the thin film transistors including a gate electrode, a source electrode, and a drain electrode;
a planarization layer, disposed on a side of the drain electrode facing away from the first base substrate, and including first through holes in a one-to-one correspondence with the plurality of thin film transistors; the first through hole exposing at least some region of a surface of the drain electrode facing away from the first base substrate;
a plurality of first electrodes, on a side of the planarization layer facing away from the first base substrate; the first electrodes being connected to the drain electrodes through the first through holes;
a plurality of first filling portions, at least within the first through holes and on a side of the first electrodes facing away from the first base substrate;
a plurality of second electrodes, on a side of the first electrodes and a side of the first filling portions facing away from the first base substrate; the second electrodes and the first electrodes being in contact with each other outside of the first through holes.

In some embodiments, the first base substrate includes a display area and a peripheral area surrounding the display area;
the display area includes a plurality of sub-pixel areas arranged in an array along a first direction and a second direction; each of the sub-pixel areas includes a first light-transmitting region and a first light-shielding region, and the first light-shielding region is on a side of the first light-transmitting region in the second direction;
an orthographic projection of the second electrode on the first base substrate overlaps with the first light-transmitting region;
an orthographic projection of the first through hole on the first base substrate is within the first light-shielding region;
an orthographic projection of the first filling portion on the first base substrate includes at least a portion within the first light-shielding region.

In some embodiments, an orthographic projection of the first electrode on the first base substrate overlaps with the first light-transmitting region;
in the first light-transmitting region and in the second direction, a width of the second electrode is greater than a width of the first electrode.

In some embodiments, the orthographic projection of the second electrode on the first base substrate overlaps with the first light-shielding region.

In some embodiments, the first electrodes and the second electrodes that are in contact with each other are staggered in the second direction.

In some embodiments, the first electrode includes: a first portion outside of the first through hole and a second portion, and the second portion is located on a side of the first portion in the second direction and is at least partially located within the first through hole;
the second electrode includes: a third portion outside the first through hole and a fourth portion, and the fourth portion is located on a side of the third portion in the second direction and is at least partially located within the first through hole;
in the second direction, a width of the first portion is smaller than a width of the third portion, and a width of the second portion is greater than a width of the fourth portion.

In some embodiments, the second portion completely covers the surface of the drain electrode exposed by the first through hole.

In some embodiments, in the second direction, an orthographic projection of a region between two adjacent second electrodes on the first base substrate overlaps with both the first light-transmitting region and the first light-shielding region.

In some embodiments, the second electrode further includes: a fifth portion on a side of the third portion facing away from the fourth portion in the second direction;
an orthographic projection of the fifth portion on the first base substrate is within the first light-shielding region;
in the second direction, an orthographic projection of a gap between two adjacent second electrodes on the first base substrate is within the orthographic projection of the first filling portion on the first base substrate.

In some embodiments, a surface of the first filling portion facing away from the first base substrate is substantially on the same plane as a surface of the first portion facing away from the first base substrate.

In some embodiments, in the first direction, a width of the first electrode is substantially equal to a width of the second electrode;
edges, extending in the second direction, at a same side of the first electrode and the second electrode substantially coincide.

In some embodiments, the array substrate further includes:
a plurality of color resists, in a one-to-one correspondence with the sub-pixel areas, and on a side of the planarization layer close to the first base substrate; where an orthographic projection of the color resist on the first base substrate covers at least the first light-transmitting region.

In some embodiments, the color resist and the drain electrode are in the same layer; the orthographic projection of the color resist on the first base substrate does not overlap with an orthographic projection of the drain electrode on the first base substrate, and the orthographic projection of the color resist on the first base substrate does not overlap with the orthographic projection of the first through hole on the first base substrate.

In some embodiments, the source electrode is located at a side of the drain electrode facing the first base substrate;
the array substrate further includes a first interlayer insulation layer between the source electrode and the drain electrode; and
the color resist and the drain electrode are located between the first interlayer insulation layer and the planarization layer.

In some embodiments, the array substrate further includes: a first signal line in the peripheral area, and a plurality of second filling portions; the first signal line is electrically connected to a third electrode;
the first signal line includes: a first sub-signal line, a second sub-signal line, and a third sub-signal line arranged in a stacked manner;
the first sub-signal line is disposed on a side of the planarization layer facing the first base substrate;
the second sub-signal line is in the same layer as the first electrode; the planarization layer further includes a plurality of second through holes penetrating through a thickness of the planarization layer, the second sub-signal line is electrically connected to the first sub-signal line through the second through hole, the second sub-signal line has a first groove at the second through hole; and the second filling portion is located within the first groove;
the third sub-signal line is in the same layer as the second electrode, the third sub-signal line is in contact with the second sub-signal line on a side of the second sub-signal line and the second filling portion facing away from the first base substrate.

In some embodiments, an orthographic projection of the second filling portion on the first base substrate is within an orthographic projection of the second sub-signal line on the first base substrate and an orthographic projection of the third sub-signal line on the first base substrate.

In some embodiments, the first sub-signal line is in the same layer as the source electrode.

In some embodiments, in the display area, the array substrate further includes: a third electrode on a side of the second electrode facing away from the first base substrate;
the first signal line further includes: a fourth sub-signal line in the same layer as the third electrode;
the array substrate further includes: a first protection layer between the third sub-signal line and the fourth sub-signal line; the fourth sub-signal line is electrically connected to the third sub-signal line via a through hole penetrating through the first protection layer.

In some embodiments, the peripheral area includes: a first bonding area on a side of the display area in the second direction;
the array substrate further includes: a plurality of bonding electrodes in the first bonding area;
the planarization layer further includes a third through hole, an orthographic projection of the bonding electrode on the first base substrate is within an orthographic projection of the third through hole on the first base substrate.

In some embodiments, the bonding electrode includes: a first sub-electrode, a second sub-electrode, a third sub-electrode, and a fourth sub-electrode;
the first sub-electrode is disposed on a side of the planarization layer facing the first base substrate;
the second sub-electrode is in the same layer as the first electrode and is electrically connected to the first sub-electrode;
the third sub-electrode is in the same layer as the second electrode and is electrically connected to the second sub-electrode;
the array substrate further includes: a third filling portion within the third through hole and between the second sub-electrode and the third sub-electrode;
the fourth sub-electrode is in contact with the third sub-electrode on a side of the third sub-electrode facing away from the first base substrate.

In some embodiments, the array substrate includes a third electrode; the fourth sub-electrode is in the same layer as the third electrode.

In some embodiments, a distance between a surface of the bonding electrode facing away from the first base substrate and the first base substrate is less than a distance between a surface of the planarization layer facing away from the first base substrate and the first base substrate, and the surface of the bonding electrode facing away from the side of the first base substrate is not covered.

In some embodiments, the array substrate further includes: a third filling portion in a part of an area inside the third through hole; an orthographic projection of the third filling portion on the first base substrate does not overlap with an orthographic projection of a surface of the bonding electrode exposed by the third through hole and facing away from the first base substrate on the first base substrate.

In some embodiments, orthographic projections of the plurality of bonding electrodes on the first base substrate are all within an orthographic projection of the same third through hole on the first base substrate.

Embodiments of the disclosure provide a preparation method of an array substrate, including:
providing a first base substrate;
forming a plurality of thin film transistors on a side of the first base substrate; where each of the thin film transistors includes a gate electrode, a source electrode, and a drain electrode;
forming a planarization layer on a side of the plurality of thin film transistors facing away from the first base substrate and forming a plurality of first through holes in the planarization layer; where the first through holes are in a one-to-one correspondence with the thin film transistors, the first through hole exposes at least some region of a surface of the drain electrode facing away from the side of the first base substrate;
forming a pattern of a plurality of first electrodes on a side of the planarization layer facing away from the first base substrate; where the first electrodes are connected to the drain electrodes through the first through holes;
forming a pattern of first filling portions on a side of the first electrodes facing away from the first base substrate and in regions of the first through holes;
forming a pattern of a plurality of second electrodes on a side of the first electrodes and a side of the first filling portions facing away from the first base substrate; where the second electrodes and the first electrodes are in contact with each other outside the first through holes.

In some embodiments, the forming the pattern of the first filling portions on the side of the first electrodes facing away from the first base substrate and in the regions of the first through holes, further includes:
forming a filling layer;
performing a patterning process on the filling layer to form a pattern of the first filling portions in the regions of the first through holes.

In some embodiments, the first base substrate includes a display area and a peripheral area surrounding the display area;
before forming the planarization layer, the method further including:
forming a first sub-signal line of a first signal line;
while forming the plurality of first through holes, the method further including:
forming a plurality of second through holes penetrating through a thickness of the planarization layer in the planarization layer;
while forming the pattern of the plurality of first electrodes, the method further including:
forming a pattern of a second sub-signal line of the first signal line; where the second sub-signal line is electrically connected to the first sub-signal line via the second through holes;
while performing the patterning process on the filling layer to form the pattern of the first filling portions in the regions of the first through holes, the method further including:
forming a pattern of a second filling portion in the region of the second through hole;
while forming the pattern of the plurality of second electrodes, the method further including:
forming a pattern of a third sub-signal line of the first signal line on a side of the second filling portion facing away from the first base substrate.

In some embodiments, the first base substrate includes a display area and a peripheral area surrounding the display area; the peripheral area includes: a first bonding area on a side of the display area in the second direction;
before forming the planarization layer, the method further including:
forming a first sub-electrode of the bonding electrode;
while forming the plurality of first through holes, the method further including:
forming a third through hole in the planarization layer; where an orthographic projection of the bonding electrode on the first base substrate is within an orthographic projection of the third through hole on the first base substrate;
while forming the pattern of the plurality of first electrodes, the method further including:
forming a pattern of a second sub-electrode of the bonding electrode; where the second sub-electrode is electrically connected to the first sub-electrode through the third through hole;
while performing the patterning process on the filling layer to form the pattern of the first filling portions in the regions of the first through holes, the method further including:
forming a pattern of a third filling portion in a region of the third through hole;
while forming the pattern of the plurality of second electrodes, the method further including:
forming a pattern of a third sub-electrode of the bonding electrode on a side of the third filling portion facing away from the first base substrate.

In some embodiments, the first base substrate includes a display area and a peripheral area surrounding the display area; the peripheral area includes: a first bonding area on a side of the display area in the second direction;
while forming the plurality of first through holes, the method further including:
forming a third through hole in the planarization layer; where an orthographic projection of the bonding electrode on the first base substrate is within an orthographic projection of the third through hole on the first base substrate;
while performing the patterning process on the filling layer to form the pattern of the first filling portions in the regions of the first through holes, the method further including:
removing the filling layer at the third through hole.

In some embodiments, after removing the filling layer at the third through hole, further including:
detecting whether the filling layer remains at the third through hole; and if the filling layer remains at the third through hole, removing the filling layer by performing an exposure and development process on all filling layers at the third through hole again.

In some embodiments, the first base substrate includes a display area and a peripheral area surrounding the display area; the peripheral area includes: a first bonding area on a side of the display area in the second direction;
while forming the plurality of first through holes, the method further including:
forming a third through hole in the planarization layer; where an orthographic projection of the bonding electrode on the first base substrate is within an orthographic projection of the third through hole on the first base substrate;
while performing the patterning process on the filling layer to form the pattern of the first filling portions in the regions of the first through holes, the method further including:
removing a part of the filling layer at the third through hole to form a third filling portion and a plurality of first removal areas; where an orthographic projection of the third filling portion on the first base substrate does not overlap with an orthographic projection of a surface of the bonding electrode facing away from the first base substrate on the first base substrate, and the orthographic projection of the surface of the bonding electrode facing away from the first base substrate on the first base substrate is within an orthographic projection of the first removal area on the first base substrate.

Embodiments of the disclosure provide a display panel, including:
the array substrate according to the embodiments of the disclosure;
an opposing substrate, opposite to the array substrate;
a liquid crystal layer, between the array substrate and the opposing substrate.

In some embodiments, the array substrate includes a first light-transmitting region; the opposing substrate includes:
a second base substrate;
a first light-shielding pattern, disposed on a side of the second base substrate facing the liquid crystal layer, and including a plurality of first openings; where an orthographic projection of the first light-shielding pattern on the first base substrate covers the first light-shielding region.

Embodiments of the disclosure provide a display device, including a display panel according to embodiments of the disclosure.

### BRIEF DESCRIPTION OF FIGURES

In order to more clearly illustrate the technical solutions in the embodiments of the present disclosure, the accompanying drawings that need to be used in the description of the embodiments will be briefly introduced below. Obviously, the accompanying drawings in the following description are only some of the embodiments of the present disclosure, and for the person of ordinary skill in the field, other accompanying drawings can be obtained based on these drawings without creative labor.

FIG. 1 is a schematic structural diagram of a display panel provided by the related art.

FIG. 2 is a schematic structural diagram of an array substrate provided by embodiments of the present disclosure.

FIG. 3 is a schematic structural diagram of another array substrate provided by embodiments of the present disclosure.

FIG. 4 is a schematic structural diagram of yet another array substrate provided by embodiments of the present disclosure.

FIG. 5 is a cross-sectional view along BB′ in FIG. 3 provided by embodiments of the present disclosure.

FIG. 6 is another cross-sectional view along BB′ in FIG. 3 provided by embodiments of the present disclosure.

FIG. 7 is a cross-sectional view along CC′ in FIG. 4 provided by embodiments of the present disclosure.

FIG. 8 is another cross-sectional view along CC′ in FIG. 4 provided by embodiments of the present disclosure.

FIG. 9 is a schematic structural diagram of another display panel provided by the related art.

FIG. 10 is a schematic structural diagram of yet another display panel provided by the related art.

FIG. 11 is a schematic structural diagram of yet another array substrate provided by embodiments of the present disclosure.

FIG. 12 is a schematic structural diagram of yet another array substrate provided by embodiments of the present disclosure.

FIG. 13 is a schematic structural diagram of yet another array substrate provided by embodiments of the present disclosure.

FIG. 14 is a schematic structural diagram of yet another array substrate provided by embodiments of the present disclosure.

FIG. 15 is a schematic structural diagram of yet another array substrate provided by embodiments of the present disclosure.

FIG. 16 is a schematic structural diagram of yet another array substrate provided by embodiments of the present disclosure.

FIG. 17 is a schematic structural diagram of yet another array substrate provided by embodiments of the present disclosure.

FIG. 18 is a schematic structural diagram of yet another array substrate provided by embodiments of the present disclosure.

FIG. 19 is a schematic structural diagram of yet another array substrate provided by embodiments of the present disclosure.

FIG. 20 is a cross-sectional view along KK′ in FIG. 19 provided by embodiments of the present disclosure.

FIG. 21 is another cross-sectional view along KK′ in FIG. 19 provided by embodiments of the present disclosure.

FIG. 22 is yet another cross-sectional view along KK′ in FIG. 19 provided by embodiments of the present disclosure.

FIG. 23 is yet another cross-sectional view along KK′ in FIG. 19 provided by embodiments of the present disclosure.

FIG. 24 is a flow diagram of a preparation method of an array substrate provided by embodiments of the present disclosure.

FIG. 25 is a flow diagram of another preparation method of an array substrate provided by embodiments of the present disclosure.

FIG. 26 is a flow chart of yet another preparation method of an array substrate provided by embodiments of the present disclosure.

FIG. 27 is a flow chart of yet another preparation method of an array substrate provided by embodiments of the present disclosure.

FIG. 28 is a schematic structural diagram of a display panel provided by embodiments of the present disclosure.

FIG. 29 is a schematic structural diagram of a display device provided by embodiments of the present disclosure.

### DETAILED DESCRIPTION

In order to make the objects, technical solutions and advantages of the embodiments of the present disclosure clearer, the technical solutions of the embodiments of the present disclosure will be described clearly and completely in the following in conjunction with the accompanying drawings of the embodiments of the present disclosure. Obviously, the described embodiments are a part but not all of the embodiments of the present disclosure. And the embodiments and the features in the embodiments of the present disclosure can be combined with each other without conflict. Based on the described embodiments of the present disclosure, all other embodiments obtained by a person of ordinary skill in the art without the need for creative labor are within the scope of protection of the present disclosure.

Unless otherwise defined, technical or scientific terms used in the present disclosure shall have the ordinary meaning understood by a person of ordinary skill in the field to which the present disclosure belongs. The terms “first”, “second”, and the like as used in the present disclosure do not indicate any order, number, or significance, but are only used to distinguish different components. The words “include” or “comprise” and the like are intended to mean that a component or an object preceded by the word encompasses the components or objects listed after the word and their equivalents, and does not exclude other components or objects. Words such as “connect” or “link” are not limited to physical or mechanical connections, but may include electrical connections, whether direct or indirect.

It should be noted that the dimensions and shapes of the figures in the accompanying drawings do not reflect true proportions, but are intended to be illustrative of the present disclosure. And throughout the same or similar labeling denotes the same or similar elements or elements having the same or similar functions.

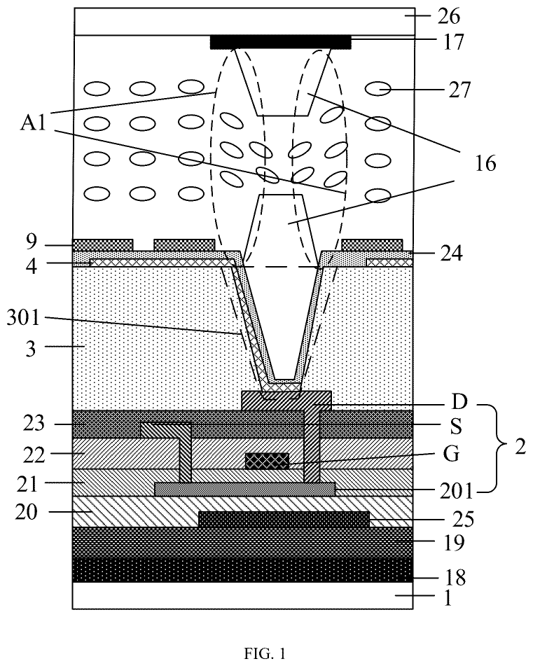

In the related art, a structure of a display panel is shown in FIG. 1. A pixel electrode P1 in an array substrate is lapped to a drain electrode D of a thin film transistor 2 via a first through hole 301 penetrating a planarization layer 3. A thickness of the pixel electrode P1 is very thin, and the thickness of the pixel electrode P1 is much smaller than a thickness of the planarization layer 3. A thickness of a first protection layer 24 covering the pixel electrode P1 is also thinner, and an area of the first through hole 301 is not filled in, and a groove region still exists at the first through hole 301 after forming the first protection layer 24. A spacer 16 arranged in the groove region has poor flatness underneath, which affects the stability of the spacer 16. If there are process variations in the spacer 16 that result in deviations in the setting position or the spacer 16 set at the first through hole 301 is extruded, it will result in the existence of a groove region at the edge of the spacer 16, where liquid crystals 27 deflect abnormally under the drive of an electric field with a risk of light leakage, and it is necessary to make a light-shielding pattern 17 included in an opposing substrate shield a light leakage risk region A1, resulting in the increase in the size of the light-shielding pattern 17, which affects the aperture ratio of the sub-pixels. Especially for high pixels per inch display products, the size of the sub-pixels is very small, and if the light-shielding pattern is utilized to block the light leakage risk region caused by the through hole of the planarization layer, the aperture ratio of the sub-pixels is seriously lost, affecting the display effect.

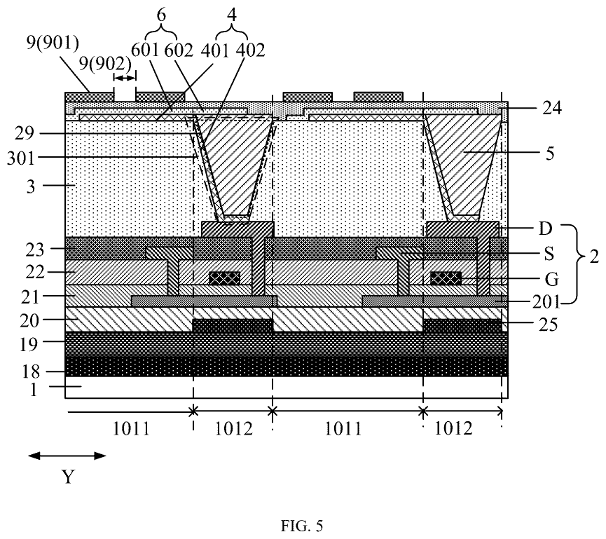

Embodiments of the present disclosure provide an array substrate, as shown in FIGS. 5 to 8, the array substrate includes:
a first base substrate 1;
a plurality of thin film transistors 2, on a side of the first base substrate 1; where the thin film transistor 2 includes: a gate electrode G, a source electrode S, and a drain electrode D;
a planarization layer 3, on a side of the drain electrode D facing away from the first base substrate 1, the planarization layer 3 including first through holes 301 in a one-to-one correspondence with the thin film transistors 2; the first through hole 301 exposing at least a part of a region of a surface of the drain electrode D facing away from the side of the first base substrate 1;
a plurality of first electrodes 4, on a side of the planarization layer 3 facing away from the first base substrate 1; where the first electrodes 4 are connected to the drain electrodes D through the first through holes 301;
a plurality of first filling portions 5, at least within the first through holes 301 and on a side of the first electrodes 4 facing away from the first base substrate 1;
a plurality of second electrodes 6, on a side of the first electrodes 4 facing away from the first base substrate 1 and on a side of the first filling portions 5 facing away from the first base substrate 1;
where the second electrodes 6 and the first electrodes 4 are in contact with each other outside the first through holes 301.

In the array substrate provided by embodiments of the present disclosure, the first filling portion is used to fill in the first through hole on a side of the first electrode facing away from the drain electrode, to improve the flatness of the region of the array substrate at the first through hole, thereby improving the thickness uniformity of the array substrate. When the array substrate is applied to a liquid crystal display panel, a light leakage risk region due to liquid crystal disorder caused by a groove region at the edge of a spacer at the first through hole can be avoided. As such, a light-shielding pattern does not need to cover the light leakage risk region, and the size of the light-shielding pattern can be reduced, thereby increasing the aperture ratio of the sub-pixel. In particular, for a display product of high pixels per inch (PPI), even if the size of the sub-pixel is small, the aperture ratio of the sub-pixel is not lost because the light leakage risk region does not need to be blocked, i.e., the array substrate provided by the embodiments of the present disclosure can be applied to a display product of high pixels per inch. Moreover, in the embodiments of the present disclosure, the array substrate further includes a second electrode in contact with the first electrode outside the first through hole on the side of the first electrode facing away from the first base substrate, that is, the second electrode is electrically connected to the drain electrode through the first electrode. When the array substrate is applied to a liquid crystal display panel, the light effect of the liquid crystal display panel is determined by the second electrode, and there is no need to avoid the first through hole for setting the size of the second electrode, which is favorable for improving the light effect by increasing the size of the second electrode.

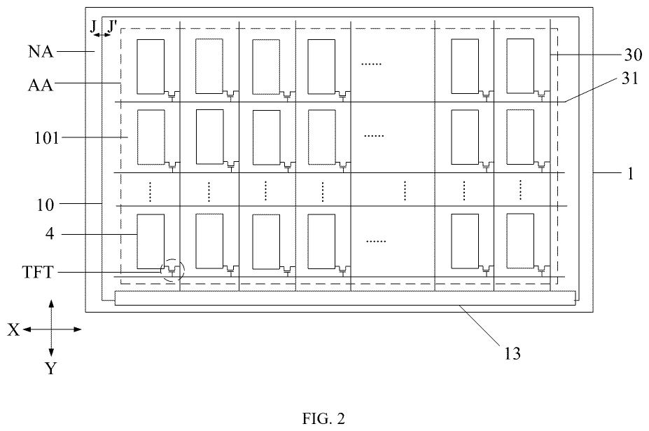

In some embodiments, as shown in FIG. 2, the first base substrate 1 includes a display area AA and a peripheral area NA surrounding the display area AA; the display area AA includes a plurality of sub-pixel areas 101 arrange in an array along a first direction X and a second direction Y.

In some embodiments, as shown in FIG. 2, the array substrate further includes: a first signal line(s) 10 in the peripheral area NA.

In some embodiments, as shown in FIGS. 5 to 8, the array substrate further includes:
a third electrode(s) 9, on a side of the second electrode(s) 6 facing away from the first base substrate 1.

In specific implementations, the first signal line is electrically connected to the third electrode.

In specific implementations, the second electrode serves as a pixel electrode, the first electrode can be regarded as a connection electrode between the second electrode and the drain electrode, the third electrode serves as a common electrode, and the first signal line provides a common voltage signal to the third electrode. The first electrode, the second electrode, and the third electrode all include a transparent material. The transparent material is, for example, indium tin oxide or the like.

In some embodiments, as shown in FIG. 2, the array substrate further includes: a plurality of second signal lines 30 and a plurality of scan lines 31 crossed horizontally and vertically; the second signal lines 30 extend from the display area AA to the peripheral area NA along the first direction X, and the scan lines 31 extend from the display area AA to the peripheral area NA along the second direction Y; and the scan lines 31 are electrically connected to gate electrodes of the thin film transistors TFT.

In specific implementations, the second signal line and the scan line generally include metallic materials. Both the second signal line and the scan line in the display area are located in a first light-shielding region, i.e., the second signal line and the scan line are blocked by a light-shielding pattern.

In specific implementations, in FIG. 2, each scan line 31 corresponds to a row of sub-pixel areas 101 arranged along the first direction X, and only one scan line 31 is included between two adjacent sub-pixel areas 101 in the second direction Y; the plurality of second signal lines 30 are data lines, and the second signal lines 30 are electrically connected to source electrodes of the thin film transistors TFT.

Alternatively, in specific implementations, it is also possible that a row of sub-pixel areas arranged in the first direction X corresponds to two scan lines, and two scan lines are included between two adjacent sub-pixel areas in the second direction Y; the plurality of second signal lines include a plurality of data lines and a plurality of common voltage lines; the data lines and the common voltage lines are arranged in alternating rows in the first direction; and the common voltage lines are also electrically connected to the third electrodes.

In some embodiments, due to a large difference in thickness between the planarization layer and the first electrode, as shown in FIGS. 5 to 8, the first electrode 4 does not fill the first through hole 301, and the first electrode 4 is lapped with the drain electrode D to form a groove 29 at the first through hole 301, and the first filling portion 5 fills the groove 29.

In some embodiments, as shown in FIGS. 5 to 8, the first through hole 301 has a trapezoidal shape in a cross-section in a direction perpendicular to the first base substrate 1, and a cross-sectional area of the first through hole 301 parallel to the first base substrate 1 gradually increases in a direction away from the first base substrate 1. That is, the planarization layer 3 has a beveled side at the first through hole 301, which is conducive to the extension of the first electrode 4 to the bottom of the first through hole 301 to lap with the drain electrode D, and avoids the risk of lap breakage at the first through hole 301.

In some embodiments, as shown in FIGS. 5 to 8, a distance between a surface of the first filling portion 5 facing away from a side of the first base substrate 1 and the first base substrate 1 is not less than a distance between a surface of the planarization layer 3 facing away from the side of the first base substrate 1 and the first base substrate 1. That is, the first filling portion and the first electrode at the first through hole fill at least the first through hole, further improving the flatness of the region of the first through hole.

In the array substrate provided in the embodiments of the present disclosure, the first filling portion and the first electrode at the first through hole fill at least the first through hole, so that even after the subsequent film layer is formed, there will not be a groove region in the region corresponding to the first through hole, and the entire region corresponding to the first through hole is no longer a light leakage risk region due to liquid crystal disorder, and the light-shielding pattern can be set without taking into account the size of the first through hole, which is conducive to increasing the aperture ratio of the sub-pixel.

In some embodiments, as shown in FIGS. 5 to 8, a surface of the first filling portion 5 facing away from the first base substrate 1 and a surface of the first electrode 4 facing away from the first base substrate 1 and located outside the first through hole 301 are approximately located in the same plane.

It should be noted that the surface of the first filling portion facing away from the first base substrate and the surface of the first electrode facing away from the first base substrate and located outside the first through hole being approximately located in the same plane means: a difference, between a distance from the surface of the first filling portion facing away from the first base substrate to the first base substrate and a distance from the surface of the first electrode facing away from the first base substrate and located outside the first through hole to the first base substrate, being within a reasonable error range indicates that the surface of the first filling portion facing away from the first base substrate and the surface of the first electrode facing away from the first base substrate and located outside the first through hole are located in the same plane.

In the array substrate provided in the embodiments of the present disclosure, the surface of the first filling portion facing away from the side of the first base substrate and the surface of the first electrode facing away from the side of the first base substrate and located outside the first through hole are located in the same plane, improving the flatness of the film layer. Moreover, since the second electrode is located at one sides of the first electrode and the first filling portion facing away from the side of the first base substrate and the surface of the first filling portion facing away from the side of the first base substrate and the surface of the first electrode facing away from the side of the first base substrate and located outside the first through hole are located in the same plane, the flatness of the second electrode can also be improved.

It should be noted that FIGS. 5 and 7 illustrate by way of example that the area of the first filling portion 5 outside the first through hole 301 does not cover the planarization layer 3. An orthographic projection of the first filling portion 5 on the first base substrate 1 coincides with an orthographic projection of the first through hole 301 on the first base substrate 1. In this way, in a preparation process of the array substrate, the same mask board can be used for the patterning process of the first filling portion and the first through hole, which can save cost.

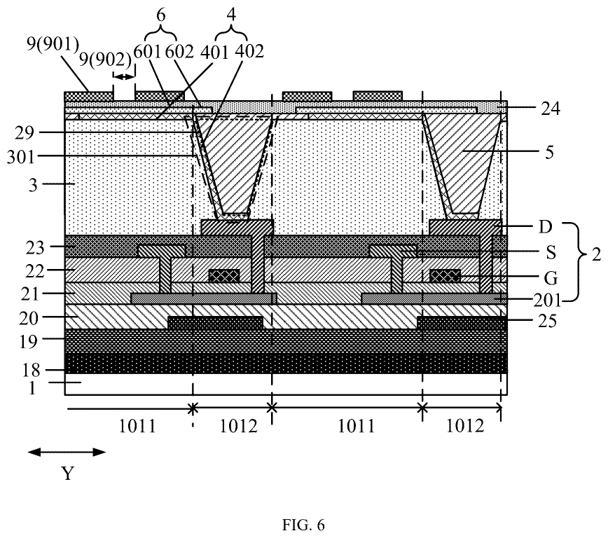

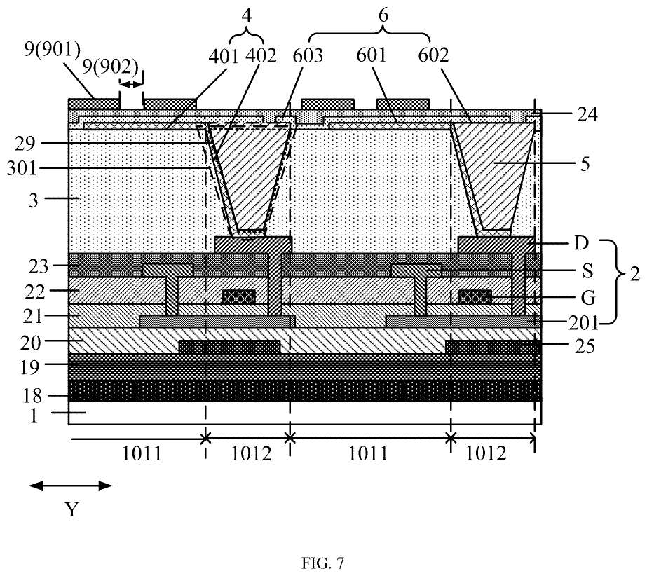

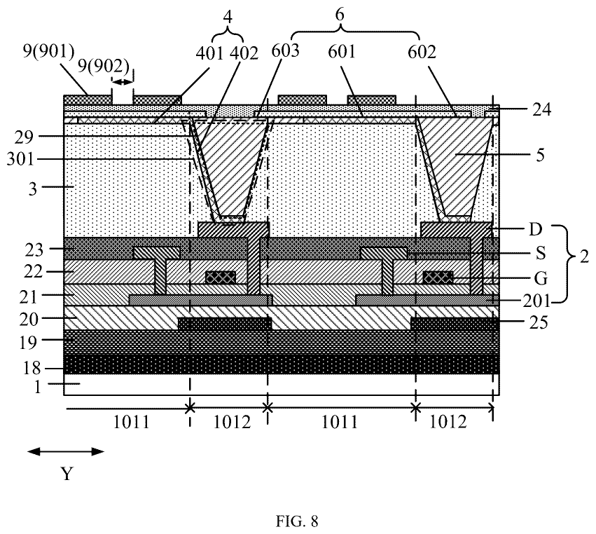

Alternatively, in some embodiments, as shown in FIGS. 6 and 8, while the surface of the first filling portion 5 facing away from the first base substrate 1 and the surface of the portion of the first electrode 4 outside of the first through hole 301 facing away from the first base substrate 1 are approximately located in the same plane, in the region outside of the first through hole 301, the first filling portion 5 covers the planarization layer 3 and is in contact with the side surface of the portion of the first electrode 4 outside of the first through hole 301, so that the orthographic projection of the first filling portion 5 on the first base substrate 1 is complementary in shape to the orthographic projection of the portion of the first electrode 4 outside the first through hole 301 on the first base substrate 1, and the surface of the film layer below the second electrode is flat in any region, improving the flatness of the surface for disposing the second electrode.

In specific implementations, the material of the planarization layer is the same as the material of the first filling portion. For example, the material of the planarization layer and the material of the first filling portion include: polyimide.

In some embodiments, as shown in FIGS. 5 to 8, the array substrate further includes: a first protection layer 24 on a side of the second electrode 6 facing away from the first base substrate 1. Specifically, the first protection layer 24 is between the second electrode 6 and the third electrode 9.

In the array substrate provided by the embodiments of the present disclosure, since the first filling portion and the first electrode at the first through hole fill the first through hole, the surface of the first filling portion facing away from the side of the first base substrate and the surface of the first electrode facing away from the side of the first base substrate and located outside the first through hole are located in the same plane. In the region corresponding to the first through hole, the surface of the first protection layer facing away from the first base substrate is planar, i.e., the first protection layer will not have a concave region at the first through hole as in the related art. Thus, when the array substrate is applied to the liquid crystal display panel, in the region corresponding to the first through hole, the flatness under the spacer is good, and the edge of the spacer does not have a concave region, avoiding the existence of a light leakage risk region due to liquid crystal disorder. Thereby, the light-shielding pattern of the liquid crystal display panel does not need to block the light leakage risk region in the related art, and the size of the light-shielding pattern can be reduced, thereby increasing the aperture ratio of the sub-pixel.

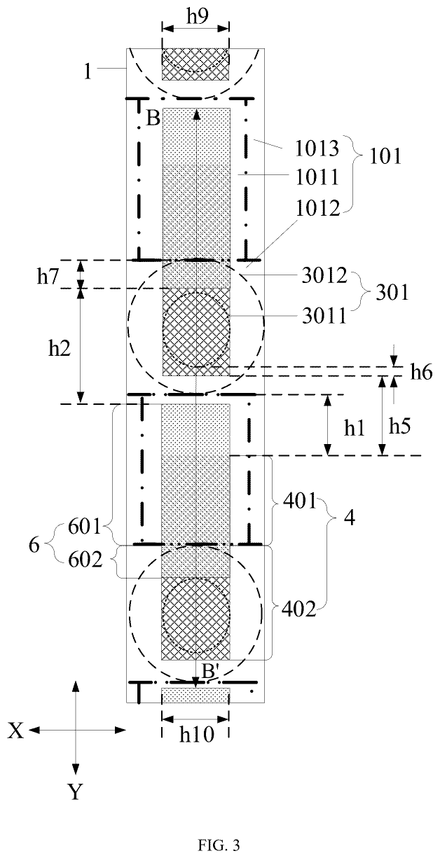

In some embodiments, as shown in FIGS. 3, 4, and 5 to 8, the sub-pixel area 101 includes: a first light-transmitting region 1011 and a first light-shielding region 1012. The first light-shielding region 1012 is located on a side of the first light-transmitting region 1011 in the second direction Y.

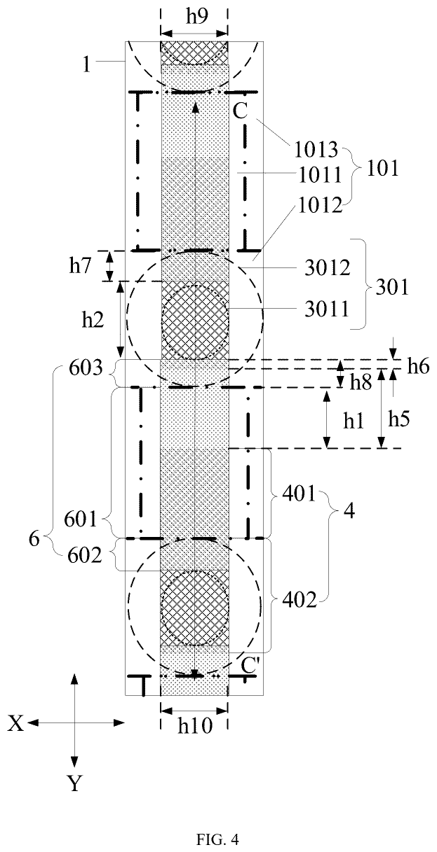

It should be noted that FIGS. 5 and 6, for example, are cross-sectional views along BB′ in FIG. 3, and FIGS. 7 and 8, for example, are cross-sectional views along CC′ in FIG. 4.

It should be noted that the liquid crystal display panel includes an array substrate and an opposing substrate opposite to the array substrate. The opposing substrate includes a first light-shielding pattern(s). The first light-shielding pattern has a plurality of first opening areas. An orthographic projection of the first opening area on the first base substrate has an overlap with the first light-transmitting region.

In some embodiments, as shown in FIGS. 5 to 8, the array substrate further includes:
a plurality of second light-shielding patterns 25 between the first base substrate 1 and the thin film transistors TFT.

In some embodiments, as shown in FIGS. 5 to 8, the first light-shielding region 1012 overlaps with an orthographic projection of the second light-shielding pattern 25 on the first base substrate 1. That is, the first light-shielding region 1012 is the region shielded by the second light-shielding pattern 25. The orthographic projection of the second light-shielding pattern 25 on the first base substrate 1 covers at least an orthographic projection of a channel of the thin film transistor on the first base substrate 1. For example, the second light-shielding pattern includes a light-shielding conductive material.

In some embodiments, as shown in FIGS. 3 and 4, the sub-pixel area 101 further includes a second light-shielding region 1013. The second light-shielding region 1013 is on a side of the first light-transmitting region 1011 in the first direction X.

Alternatively, in some embodiments, an orthographic projection of the first opening area on the first base substrate coincides with the first light-transmitting region; in the display area, an orthographic projection of the first light-shielding pattern on the first base substrate coincides with orthographic projections of all of the first light-shielding regions and all of the second light-shielding regions of the plurality of sub-pixel areas on the first base substrate.

In specific implementations, for example, the orthographic projection of the first light-shielding pattern on the first base substrate covers the orthographic projection of the second light-shielding pattern on the first base substrate. In specific implementations, for example, a width of the first light-shielding pattern is greater than or equal to a width of the second light-shielding pattern in the second direction Y, between adjacent opening areas.

In some embodiments, as shown in FIGS. 3, 4, and 5 to 8, an orthographic projection of the second electrode 6 on the first base substrate 1 overlaps with the first light-transmitting region 1011.

In specific implementations, when the array substrate provided in the embodiments of the present disclosure is applied to a liquid crystal display panel, an orthographic projection of an opening area of the display panel on the first base substrate is within an orthographic projection of the second electrode on the first base substrate.

In some embodiments, as shown in FIGS. 5 to 8, no insulation layer is provided between the second electrode 6 and the first electrode 4 in the region beyond the first through hole 301, i.e., the second electrode 6 is directly lapped with the first electrode 4 in the region beyond the first through hole 301.

It should be noted that since the second electrode is located on the side of the first electrode facing away from the base substrate, the size of the second electrode is the size of the pixel electrode, so when the array substrate provided in the embodiments of the present disclosure is applied to a liquid crystal display panel, the size of the region for driving the deflection of the liquid crystal is related to the size of the second electrode but not to the size of the first electrode. The larger the size of the region in which the orthographic projection of the second electrode on the first base substrate overlaps with the first light-transmitting region is, the more favorable to improve the aperture ratio of the display panel is, thereby improving the light effect of the display panel.

In some embodiments, as shown in FIGS. 3, 4, and 5 to 8, the orthographic projection of the first through hole 301 on the first base substrate 1 is within the first light-shielding region 1012.

As shown in FIGS. 5 to 8, an orthographic projection of the first filling portion 5 on the first base substrate 1 is at least partially within the first light-shielding region 1012.

In specific implementations, when the array substrate is applied to a display panel, the first light-shielding region is covered by the second light-shielding pattern, and the first through hole corresponds to the area of the drain electrode of the thin film transistor, i.e., the drain electrode is provided in the first light-shielding region and covered by the second light-shielding pattern, so as to avoid light leakage caused by reflections of the metal material of the drain electrode.

In some embodiments, as shown in FIGS. 5 and 7, the first filling portion 5 is located only in the region corresponding to the first opening 3011, and the first filling portion 5 does not cover the planarization layer 3 and the first electrode 4 in the region outside of the first through hole 301, and the orthographic projection of the first filling portion 5 on the first base substrate 1 is within the first light-shielding region 1012. Alternatively, as shown in FIGS. 6 and 8, the first filling portion 5 covers the planarization layer 3 in the region outside of the first through hole 301, and the orthographic projection of the first filling portion 5 on the first base substrate 1 overlaps both the first light-shielding region 1012 and the first light-transmitting region 1011.

In some embodiments, as shown in FIGS. 3 and 4, the first light-shielding region 1012 is on a side of the first light-transmitting region 1011 in the second direction Y. Accordingly, the orthographic projection of the first through hole 301 on the first base substrate 1 is on the side of the first light-transmitting region 1011 in the second direction Y.

In some embodiments, as shown in FIGS. 3 and 4, the planarization layer (not shown) has a first opening 3011 and a second opening 3012 at the first through hole 301. The first opening 3011 is an opening of a surface of the planarization layer close to the side of the first base substrate 1, i.e., an opening for exposing the drain electrode of the thin film transistor (not shown). An area of the first opening 3011 is an area of the drain electrode of the thin film transistor exposed by the first through hole 301. The second opening 3012 is an opening of a surface of the planarization layer away from the side of the first base substrate 1.

In some embodiments, as shown in FIGS. 3 and 4, orthographic projections of the first opening 3011 and the second opening 3012 on the first base substrate 1 are both circular. A diameter of the first opening 3011 is smaller than a diameter of the second opening 3012. An orthographic projection of the first opening 3011 on the first base substrate 1 is within an orthographic projection of the second opening 3012 on the first base substrate 1.

In some embodiments, as shown in FIGS. 3 and 4, a width of the first light-shielding region 1012 is approximately equal to the diameter of the second opening 3012 in the second direction Y. That is, a difference between the width of the first light-shielding region and the diameter of the second opening is within an error range allowed, which can be regard as the width of the first light-shielding region being equal to the diameter of the second opening.

In the array substrate provided in the embodiments of the present disclosure, the first filling portion is provided in the first through hole to improve the flatness of the array substrate, even if the area near the edge of the first through hole is no longer located in the light-shielding region, the problem of light leakage due to the through hole will not occur. The width of the first light-shielding region is equal to the diameter of the second opening, which can improve the aperture ratio of the sub-pixel while avoiding reflection of the metal material.

In some embodiments, as shown in FIGS. 3 to 8, since the orthographic projection of the first through hole 301 on the first base substrate 1 is within the first light-shielding region 1012, the orthographic projection of the portion of the first electrode 4 in the first through hole 301 on the first base substrate 1 is also within the first light-shielding region 1012. Since the width of the first light-shielding region 1012 in the second direction Y is approximately equal to the diameter of the second opening 3012, the orthographic projection of the first electrode 4 in the region outside the first through hole 301 in the second direction Y on the first base substrate 1 is located in the first light-transmitting region 1011. That is, the orthographic projection of the first electrode 4 on the first base substrate 1 overlaps with both the first light-transmitting region 1011 and the first light-shielding region 1012.

In some embodiments, as shown in FIGS. 3 and 4, in the second direction Y, the orthographic projection of the first electrode 4 on the first base substrate 1 does not overlap the orthographic projection of the first through hole 301 corresponding to a sub-pixel area 101 adjacent to the first electrode 4 on the first base substrate 1. Thereby, it can be avoided that the first electrode falling into the first through hole of the sub-pixel area adjacent to the first electrode causes the first electrode of the adjacent sub-pixel to lap at the first through hole.

In some embodiments, as shown in FIGS. 3 and 4, in the second direction Y, a distance h1 between the first electrode 4 and the second opening 3012 corresponding to the sub-pixel area 101 adjacent to the first electrode 4 is greater than or equal to a first preset value.

It should be noted that the first preset value is a minimum value to avoid the first electrode from falling into the first through hole of the sub-pixel area adjacent to the first electrode under consideration of the fluctuation of the alignment of the planarization layer and the first electrode, and the fluctuation of the size of the first opening.

In the array substrate in the embodiments of the present disclosure, h1 is greater than or equal to the first preset value, so as to prevent the first electrodes of the adjacent sub-pixel areas from lapping at the first through hole due to a process error.

In specific implementations, the first preset value varies with different capabilities of the equipment for preparing the array substrate. The first preset value is, for example, 1 micron, 0.5 micron, and the like.

In some embodiments, as shown in FIGS. 3, 4, and 5 to 8, in the first light-transmitting region 1011 and in the second direction Y, the width of the second electrode 6 is greater than the width of the first electrode 4.

It should be noted that in the related art, considering process variations, such as the fluctuation of the alignment of the planarization layer and the first electrode, and the fluctuation of the size of the first opening, in order to prevent the first electrodes of the adjacent sub-pixels from lapping at the first through hole, i.e., in order to avoid the first portion from falling into the first through hole, the first electrode has a smaller size in the first light-transmitting region, and thus the size of the first electrode limits the aperture ratio of the sub-pixel, which further affects the light effect of the liquid crystal display panel.

In the array substrate provided in the embodiments of the present disclosure, since the side of the first electrode facing away from the first base substrate is further provided with a second electrode, the size of the first electrode does not limit the aperture ratio of the sub-pixel. Since the second electrode is also not electrically connected to the first electrode at the first through hole of the adjacent sub-pixel area, even if the second electrode extends to the first through hole of the adjacent sub-pixel area, the extension of the second electrode does not result in the electrode conduction of adjacent sub-pixels. Thus, the width of the second electrode in the second direction and in the first light-transmitting region is larger than the width of the first electrode, thereby avoiding the first electrodes of the adjacent sub-pixels from lapping at the first through hole while increasing the size of the second electrode in the first light-transmitting region, increasing the aperture ratio of the sub-pixel, further increasing the light effect.

In specific implementations, in the second direction Y, when the distance h1 between the first electrode and the second opening corresponding to the adjacent sub-pixel area is equal to the first preset value, it is possible to avoid the first electrodes of the adjacent sub-pixels from lapping at the first through hole while maximizing the contact area between the first electrode and the second electrode, which can reduce the contact resistance between the first electrode and the second electrode, thus improving the conductive effect between the first electrode and the second electrode.

In some embodiments, as shown in FIGS. 3, 4, and 5 to 8, the orthographic projection of the second electrode 6 on the first base substrate 1 has an overlap with the first light-shielding region 1012.

In the array substrate provided in the embodiments of the present disclosure, the orthographic projection of the second electrode on the first base substrate overlaps with both the first light-transmitting region and the first light-shielding region, so that the size of the second electrode can be relatively large, which is conducive to increasing the size of the second electrode, and further increasing the area of the region in which the orthographic projection of the second electrode on the first base substrate overlaps with the first light-transmitting region, thereby increasing the aperture ratio of the display panel and improving the light effect of the display panel. Moreover, the orthographic projection of the second electrode on the first base substrate overlaps with both the first light-transmitting region and the first light-shielding region, which can further avoid the impact of an alignment deviation in the array substrate preparation process on the area of the region in which the orthographic projection of the second electrode on the first base substrate overlaps with the first light-transmitting region.

In some embodiments, as shown in FIGS. 5 to 8, the orthographic projection of the second electrode 6 on the first base substrate 1 has an overlap with the orthographic projection of the first filling portion 5 on the first base substrate 1. That is, the second electrode 6, in addition to covering the first electrode 4, further covers a portion of the first filling portion 5 located in the region of the first through hole 301. Thereby, the size of the second electrode can be increased to improve the light effect.

In some embodiments, in the second direction Y, in the first light-transmitting region 1011, a distance h2 between the second electrodes 6 of two adjacent sub-pixel areas is greater than or equal to a second preset value.

It should be noted that the second preset value refers to a minimum distance between adjacent patterns that can be realized by the same layer process in the array substrate preparation process. In specific implementations, when h2 is equal to the second preset value, the size of the second electrode can be maximized, which is conducive to increasing the area of the region in which the orthographic projection of the second electrode on the first base substrate has an overlap with the first light-transmitting region, thus improving the light effect.

In some embodiments, the second preset value is 1.8 microns.

In some embodiments, as shown in FIGS. 3, 4, and 5 to 8, the first electrode 4 includes: a first portion 401 outside the first through hole 301 and a second portion 402 on a side of the first portion 401 in the second direction Y and at least partially within the first through hole 301.

The second electrode 6 includes: a third portion 601 outside the first through hole 301 and a fourth portion 602 on a side of the third portion 601 in the second direction Y and at least partially within the first through hole 301.

In some embodiments, as shown in FIGS. 3, 4, and 5 to 8, the first portion 401 and the third portion 601 are located only in the first light-transmitting region 1011, and the second portion 402 and the fourth portion 602 are located only in the first light-shielding region 1012.

In some embodiments, as shown in FIGS. 3, 4, and 5 to 8, the orthographic projection of the fourth portion 602 on the first base substrate 1 has an overlap with a part of an area of the orthographic projection of the first filling portion 5 on the first base substrate 1.

That is, as shown in FIGS. 5 to 8, the third portion 601 laps with the first portion 401, the second portion 402 is covered by the first filling portion 5, and the fourth portion 602 is in contact with the first filling portion 5 on the side of the first filling portion 5 facing away from the first base substrate 1.

In some embodiments, as shown in FIGS. 5 to 8, the surface of the first filling portion 5 facing away from the side of the first base substrate 1 is substantially located in the same plane as the surface of the first portion 401 facing away from the side of the first base substrate 1.

In some embodiments, as shown in FIGS. 3, 4, and 5 to 8, the width of the first portion 401 is smaller than the width of the third portion 601 in the second direction Y.

In specific embodiments, in the second direction Y, the distance h1 between the first electrode and the second opening corresponding to the adjacent sub-pixel area is a distance between the third portion and the second opening corresponding to the adjacent sub-pixel area.

That is, the distance between the third portion and the second opening corresponding to the adjacent sub-pixel area is greater than or equal to the first preset value.

In some embodiments, as shown in FIGS. 3 and 4, in the second direction Y, a distance h5 (i.e., a distance between the first portion 401 and the second portion 402, which are located in different first electrodes 4 and are adjacent to each other) between adjacent first electrodes 4 is greater than or equal to the second preset value. That is, the distance h5 between adjacent first electrodes 4 is greater than the minimum distance between adjacent patterns achieved by the same layer process, thereby avoiding conduction between adjacent first electrodes 4.

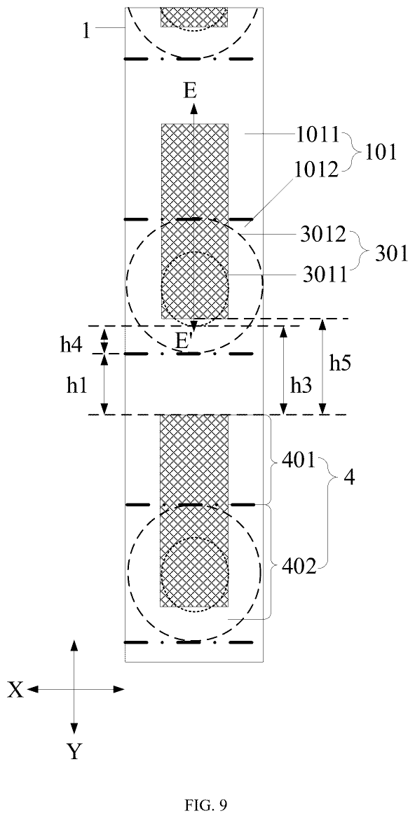

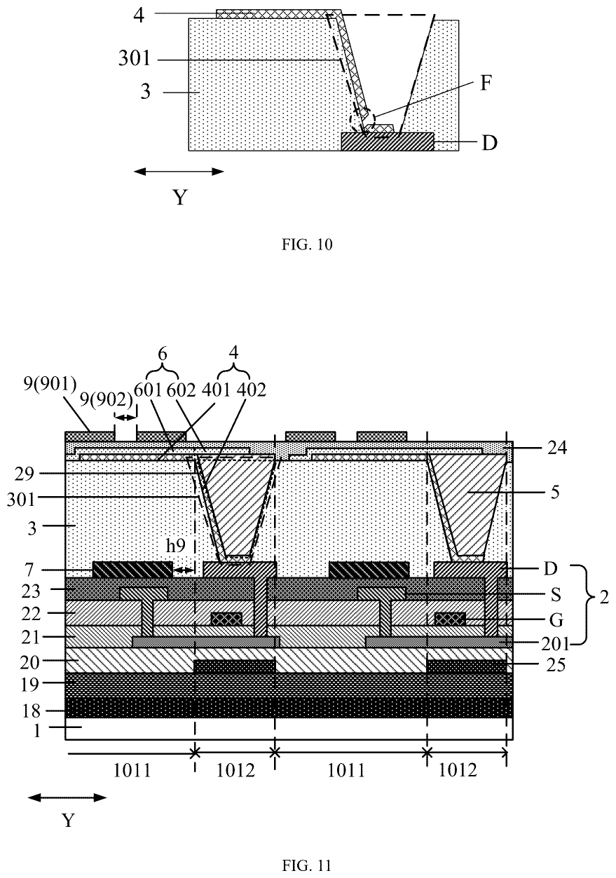

It should be noted that in the related art, the first electrode serves as a pixel electrode, and thus both the process variation and the aperture ratio of the sub-pixel need to be considered. As shown in FIG. 9, h3 indicates a distance between an orthographic projection of the first electrode 4 on the first base substrate 1 and an orthographic projection of the first opening 3011 of a sub-pixel area 101 adjacent to the first electrode 4 on the first base substrate 1, h4 indicates a distance between the orthographic projection of the first opening 3011 on the first base substrate 1 and an orthographic projection of the second opening 3012 on the first base substrate 1, and h1 indicates a distance between the orthographic projection of the first electrode 4 on the first base substrate 1 and the orthographic projection of the second opening 3012 of the sub-pixel area 101 adjacent to the first electrode 4 on the first base substrate 1, where h1 is not smaller than the first preset value. If h3 is smaller than the minimum distance between adjacent patterns realized by the same layer process for fabricating the array substrate, in the case that h3 is not changed, in order to ensure the aperture ratio of the sub-pixel and avoid the first electrodes 4 of the adjacent sub-pixel areas 101 from lapping at the first through hole 301, the first electrode 4 needs to be narrowed in such a way that the boundary of the first electrode 4 at the first through hole 301 is moved upward in order to ensure that the distance h5 between the adjacent first electrodes 4 is not smaller than the minimum distance (i.e., the second preset value) between adjacent patterns realized by the same layer process. However, it will result in the first electrode 4 not completely covering the first opening 3011, i.e., the first electrode 4 does not completely cover the drain electrode (not shown) exposed by the first opening 3011, resulting in the contact area between the first electrode 4 and the drain electrode being reduced and the contact resistance being large. Moreover, the fact that the first electrode 4 does not completely cover the first opening 3011 also causes the first electrode 4 to be insufficiently wrapped around the edge of the first through hole 301 of the planarization layer 3. Due to insufficient adhesion between the planarization layer and the first electrode caused by the moisture in the planarization layer, there will be etching solution seeping and upwardly drilling during the etching process. As shown in FIG. 10, the first electrode 4 at the side wall of the first through hole 301 is missing, for example, the first electrode 4 at region F in FIG. 10 is missing, so that a conducting path cannot be established between the portion of the first electrode 4 outside of the first through hole 301 and the drain electrode, and further the first electrode 4 cannot be charged, affecting the preparation yield of the array substrate. When the array substrate is applied to the liquid crystal display panel, dark spots will appear in the region where the first electrode 4 cannot be charged, affecting the display effect. It is noted that FIG. 10 shows a cross-sectional view along EE′ in FIG. 9.

In some embodiments, as shown in FIGS. 5 to 8, the second portion 402 completely covers the surface of the drain electrode D exposed by the first through hole 301. That is, as shown in FIGS. 3 and 4, the orthographic projection of the first opening 3011 on the first base substrate 1 is within the orthographic projection of the second portion 402 on the first base substrate 1. Accordingly, as shown in FIGS. 5 to 8, the second portion 402 covers the side of the planarization layer 3 around the bottom of the first through hole 301. Thereby, the covering effect of the second portion 402 on the bottom of the first via hole 301 can be improved, the contact area between the first electrode 4 and the drain electrode D can be improved to reduce the contact resistance, and it can be avoid that drilling in the etching process causes the first electrode 4 to be missing and unable to conduct with the drain electrode D, to improve the yield of the preparation of the array substrate, and to avoid that the array substrate being applied to the display panel causes a bad dark spot.

In the array substrate provided in the embodiments of the present disclosure, since the side of the first electrode facing away from the first base substrate is provided with a second electrode in contact with the first electrode, the size of the first electrode does not affect the aperture ratio of the sub-pixels. Thus while the orthographic projection of the first opening on the first base substrate is within the orthographic projection of the second portion on the first base substrate, it is also possible to achieve the distance between adjacent first electrodes greater than the minimum distance between adjacent patterns achieved by the same layer process without affecting the aperture ratio.

In some embodiments, in order to ensure the wrapping effect of the second portion 402 of the first electrode 4 on the bottom edge of the first through hole 301, as shown in FIGS. 3 and 4, a distance h6 between an edge of the orthographic projection of the second portion 402 on the first base substrate 1 and an edge of the orthographic projection of the first opening 3011 on the first base substrate 1 is greater than or equal to 0. It should be noted that, in FIG. 3 and FIG. 4, the following is described as an example: the distance between the edge of the orthographic projection of the second portion 402 extending along the second direction Y on the first base substrate 1 and the edge of the orthographic projection of the first opening 3011 on the first base substrate 1 is 0; and the distance between the edge of the orthographic projection of the second portion 402 extending along the first direction X and far away from the first portion 401 on the first base substrate 1, and the edge of the orthographic projection of the first opening 3011 on the first base substrate 1 is greater than 0. In specific implementations, in order to ensure the contact area between the first portion 401 of the first electrode 4 and the third portion 601 of the second electrode 6, h5 can be set to be equal to the second preset value. The distance h6 between the edge of the orthographic projection of the second portion 402 extending along the first direction X and far away from the first portion 401 on the first base substrate 1, and the edge of the orthographic projection of the first opening 3011 on the first base substrate 1 is equal to 0.

In some embodiments, as shown in FIGS. 3 and 4, a width h7 of the fourth portion 602 is greater than or equal to a third preset value in the second direction Y.

It should be noted that when the size of the second electrode fluctuates in the second direction as well as the alignment fluctuates, if h7 is smaller, in the second direction, if the edge of the fourth portion away from the third portion is shifted upwardly, it may occur that the fourth portion is shifted to the first light-transmitting region and a distance between the edge of the fourth portion far away from the third portion and the edge of the first light-shielding region closest to the fourth portion is greater than 0, which may reduce the overlapped area of the second electrode and the first light-transmitting region, thereby affecting the aperture ratio of the sub-pixel and thus affecting the light effect.

It should be noted that the third preset value is a minimum value to avoid the fourth portion failing to fall within the first light-shielding region in case of fluctuation in the size of the second electrode and fluctuation in the alignment. In this way, h7 being greater than or equal to the third preset value can avoid affecting the aperture ratio of the sub-pixel and further affecting the light effect when the size of the second electrode fluctuates and the alignment fluctuates in the second direction. The third preset value varies depending on different capabilities of the equipment for preparing the array substrate. For example, the third preset value is 1.5 microns, 0.6 microns, and so on.

In some embodiments, as shown in FIGS. 3 and 4, in the second direction Y, the first electrodes 4 and the second electrodes 6 that are in contact with each other are arranged in a staggered manner. That is, in the second direction Y, the width of the fourth portion 602 is smaller than the width of the second portion 402.

In the array substrate provided by the embodiments of the present disclosure, the width of the fourth portion is smaller than the width of the second portion and the width of the fourth portion is greater than or equal to the third preset value, which can avoid an increase in cost due to an excessively large width of the fourth portion while avoiding the impact of fluctuation of the size of the second electrode and the fluctuation of the alignment on the aperture ratio of the sub-pixel in the second direction.

In some embodiments, as shown in FIGS. 3, 5, and 6, in the second direction Y, an orthographic projection of a region between two adjacent second electrodes 6 on the first base substrate has an overlap with both the first light-transmitting region 1011 and the first light-shielding region 1012.

Alternatively, in some embodiments, as shown in FIGS. 4, 7, and 8, the second electrodes 6 further include: a fifth portion 603 on the side of the third portion 601 facing away from the fourth portion 602 in the second direction Y.

An orthographic projection of the fifth portion 603 on the first base substrate 1 is within the first light-shielding region 1012.

In the second direction Y, an orthographic projection of a gap between two adjacent second electrodes 6 on the first base substrate 1 is within the orthographic projection of the first filling portion 5 on the first base substrate 1.

That is, as shown in FIGS. 4, 7, and 8, in the second direction Y, the width of the third portion 601 is equal to the width of the first light-transmitting region 1011. The overlapped area between the third portion 601 and the first light-transmitting region 1011 can be increased, thereby improving the aperture ratio of the sub-pixel and improving the light effect.

In some embodiments, as shown in FIG. 4, in the second direction Y, the width h8 of the fifth portion 603 is greater than or equal to the third preset value.

It should be noted that when the size of the second electrode fluctuates and the alignment fluctuates in the second direction, if h8 is smaller, in the second direction, if the edge of the fifth portion away from the third portion is shifted downwardly, it may occur that the fifth portion is shifted to the first light-transmitting region and a distance between the edge of the fifth portion away from the third portion and the edge of the first light-shielding region closest to the fifth portion is greater than 0, which may reduce the overlapped area of the second electrode and the first light-transmitting region, thereby affecting the aperture ratio of the sub-pixel and thus affecting the light effect.

In the array substrate provided in the embodiments of the present disclosure, the third preset value is a minimum value to avoid the fourth portion failing to be within the first light-shielding region under fluctuations in the size of the second electrode and fluctuations in alignment, and h7 is greater than or equal to the third preset value to avoid affecting the aperture ratio of the sub-pixel and thus affecting the light effect when fluctuations in the size of the second electrode and fluctuations in alignment occur in the second direction.

In the array substrate provided by the embodiments of the present disclosure, the fourth portion and the fifth portion are both located in the first light-shielding region, i.e., both ends of the second electrode extending in the second direction are located in the first light-shielding region, and h7 and h8 are both greater than or equal to the third preset value, so that fluctuations of the size of the second electrode and fluctuations of the alignment in the second direction can be avoided from influencing the aperture ratio of the sub-pixel and further improving the aperture ratio of the sub-pixel and thereby improving the light effect.

In some embodiments, as shown in FIGS. 3 and 4, in the first direction X, a width h9 of the first electrode 4 and a width h10 of the second electrode 6 are approximately equal.

In some embodiments, as shown in FIGS. 3 and 4, the edges of the first electrode 4 and the second electrode 6 located on the same side and extending along the second direction Y substantially coincide. That is, the difference between the edges of the first electrode 4 and the second electrode 6 located on the same side and extending along the second direction Y is smaller than or equal to a reasonable process error.

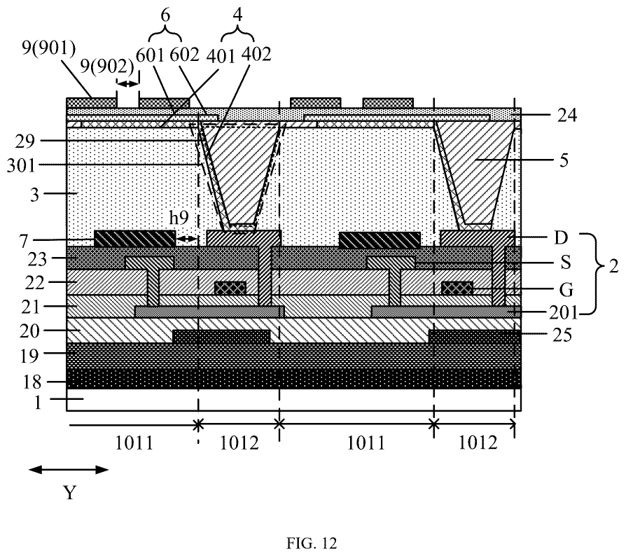

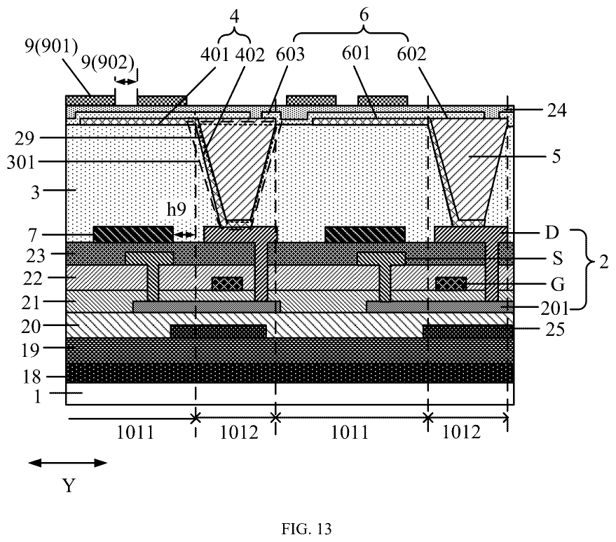

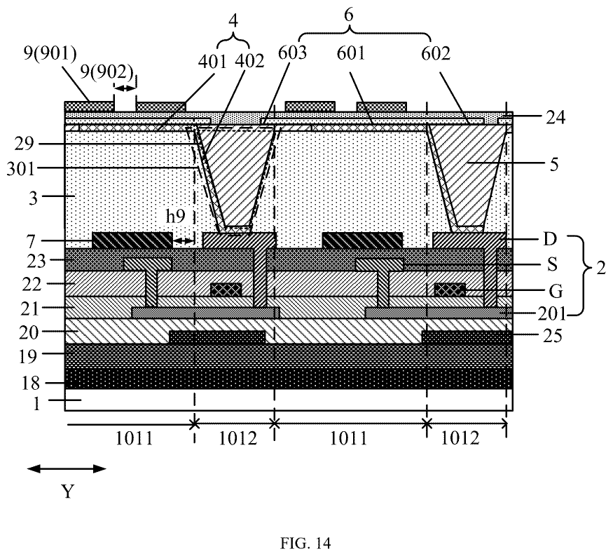

In some embodiments, as shown in FIGS. 11 to 14, the array substrate further includes:
a plurality of color resists 7, in a one-to-one correspondence with the sub-pixel areas 101, and located on a side of the planarization layer 3 close to the first base substrate 1; where an orthographic projection of the color resist 7 on the first base substrate 1 covers at least the first light-transmitting region 1011.

In the array substrate provided in the embodiments of the present disclosure, the color resists are provided in the array substrate. When the array substrate is applied to a liquid crystal display panel of high pixels per inch, the opposing substrate of the liquid crystal display panel does not need the color resists, so as to avoid the problem of mixing and stringing of colors caused by setting the color resists in the opposing substrate, and to improve the display effect.

In some embodiments, the plurality of sub-pixel areas includes a plurality of red sub-pixel areas, a plurality of blue sub-pixel areas, and a plurality of green sub-pixel areas. Accordingly, the plurality of color resists include: red color resists corresponding to the red sub-pixel areas, blue color resists corresponding to the blue sub-pixel areas, and green color resists corresponding to the green sub-pixel areas.

In some embodiments, as shown in FIGS. 11 to 14, the color resist 7 is located on the same layer as the drain electrode D.

The orthographic projection of the color resist 7 on the first base substrate 1 and the orthographic projection of the drain electrode D on the first base substrate 1 do not overlap each other. The orthographic projection of the color resist 7 on the first base substrate 1 and the orthographic projection of the first through hole 301 on the first base substrate 1 do not overlap each other.

It should be noted that since the color resist and the drain electrode are located in the same layer, in order to ensure the filtering effect of the color resist, the thickness of the color resist is usually not too thin, and thus the thickness of the planarization layer covering the color resist is also thicker. In order to avoid the risk of lapping short lines of the first electrodes at the first through hole, a side inclination angle of the planarization layer at the first through hole is relatively larger, resulting in a larger size of the second opening of the first through hole. In related art, the size of the light leakage risk region that needs to be blocked is also larger, which further affects the aperture ratio of the sub-pixel. In the array substrate provided in the embodiments of the present disclosure, even if the array substrate is provided with color resists, the occurrence of the light leakage risk region in the related art can be avoid by setting the first filling portion to fill at least the first through hole, so that there is no need to block the light leakage risk region, thereby improving the aperture ratio of the sub-pixel.

It should be noted that, as shown in FIGS. 11 to 14, the color resist 7 and the drain electrode D are located in the same layer, which refers that the color resist 7 and the drain electrode D are provided in the same film layer.

In some embodiments, as shown in FIGS. 11 to 14, the source electrode S is on a side of the drain electrode D facing the first base substrate 1; the array substrate further includes a first interlayer insulation layer between the source electrode S and the drain electrode D; and the color resist and the drain electrode D are between the first interlayer insulation layer and the planarization layer 3.

In the array substrate provided in the embodiments of the present disclosure, the source electrode and the drain electrode of the thin film transistor are located in different film layers, so that even if the distance between the edge of the orthographic projection of the source electrode on the first base substrate and the edge of the orthographic projection of the drain electrode on the first base substrate is reduced, it does not result in a short-circuit between the source electrode and the drain electrode and the difficulty of designing a layout of the array substrate can be simplified. Moreover, reducing the distance between the edge of the orthographic projection of the source electrode on the first base substrate and the edge of the orthographic projection of the drain electrode on the first base substrate can also reduce the size of the sub-pixel area, which is conducive to realizing a high pixels per inch, and thus the resolution can be improved, which is conducive to realizing a high-resolution display.

In some embodiments, as shown in FIGS. 11 to 14, the array substrate further includes: a buffer layer 18 between the second light-shielding pattern 25 and the first base substrate 1, a first insulation layer 19 between the second light-shielding pattern 25 and the buffer layer 18, a second insulation layer 20 between the second light-shielding pattern 25 and an active layer 201 of the thin film transistor 2, a third insulation layer 21 between the active layer 201 and the gate electrode G, a fourth insulation layer 22 between the gate electrode G and the source electrode S, and a fifth insulation layer 23 between the source electrode S and the drain electrode D; the color resist 7 and the drain electrode D are disposed on the fifth insulation layer 23.

In some embodiments, as shown in FIGS. 5 to 8, and FIGS. 11 to 14, the third electrode includes a plurality of strip electrode portions 901 and slits 902 arranged between adjacent strip electrode portions 901.

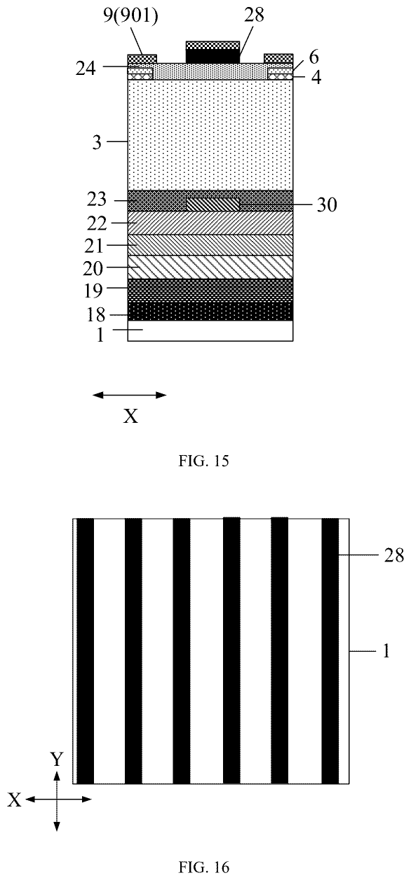

In some embodiments, as shown in FIG. 15, the array substrate further includes: a plurality of third light-shielding patterns 28.

The third light-shielding pattern 28 is arranged between the first protection layer 24 and the third electrode 9.

In some embodiments, as shown in FIG. 16, a pattern of an orthographic projection of the third light-shielding pattern 28 on the first base substrate 1 is a strip pattern extending along the second direction Y; the plurality of third light-shielding patterns 28 are arranged along the first direction X.

In some embodiments, as shown in FIG. 15, the orthographic projection of the third light-shielding pattern 28 on the first base substrate 1 substantially coincides with the orthographic projection of the second signal line 30 on the first base substrate 1.

In the array substrate provided by the embodiments of the present disclosure, the orthographic projection of the third light-shielding pattern on the first base substrate substantially coincides with the orthographic projection of the second signal line on the first base substrate, which can prevent the adjacent sub-pixels from color mixing and color stringing, improve display effect and improve the user experience.

The enhancement of light effect and the light conversion ratio of a liquid crystal display panel using the array substrate provided in the embodiments of the present disclosure will be described as follows. Based on experiments, if the light leakage problem at the edge of the first through hole of the planarization layer is not considered, when the liquid crystal display panel provided in the embodiments of the present disclosure has the same resolution and aperture ratio as the liquid crystal display panel in the related art, the array substrate provided in the embodiments of the present disclosure utilizes the first filling portion to fill in the first through hole and is provided with the second electrode, while the first filling portion and the second electrode are not provided in the related art, the light effect of the liquid crystal display panel provided in the embodiments of the present disclosure can be improved by at least 3% compared to the light effect of the liquid crystal display panel in the related art. If the light leakage problem at the edge of the first through hole of the planarization layer is considered, the first light-shielding pattern of the opposing substrate of the liquid crystal display panel in the related art is required to shield the edge of the first through hole, and if the resolution of the liquid crystal display panel provided in the embodiments of the present disclosure is equal to the resolution of the liquid crystal display panel in the related art, the aperture ratio of the liquid crystal display panel provided by the embodiments of the present disclosure is greater than the aperture ratio of the resolution of the liquid crystal display panel in the related art, and the light conversion ratio of the liquid crystal display panel provided in the embodiments of the present disclosure is increased by at least 12% compared to the light conversion ratio of the liquid crystal display panel in the related art.

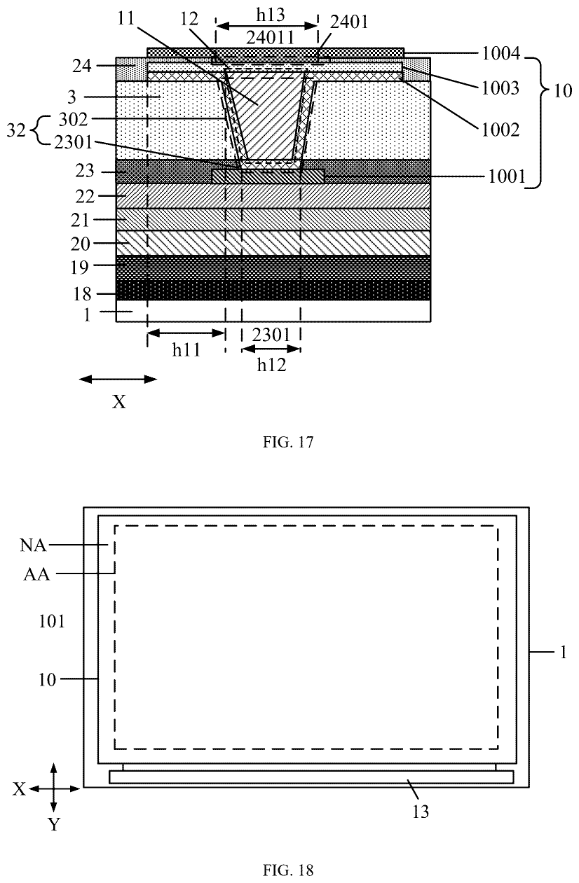

In some embodiments, as shown in FIG. 17, the first signal line 10 includes: a first sub-signal line 1001, a second sub-signal line 1002, and a third sub-signal line 1003 arranged in a stacked manner.

The first sub-signal line 1001 is on a side of the planarization layer 3 facing the first base substrate 1.

The second sub-signal line 1002 is in the same layer as the first electrode 4. The planarization layer 3 further includes a plurality of second through holes 302 penetrating the thickness of the planarization layer 3. The second sub-signal line 1002 is electrically connected to the first sub-signal line 1001 through the second through hole 302. The second sub-signal line 1002 has a first groove 12 in the second through hole 302.

The array substrate further includes: a plurality of second filling portions 11. The second filling portion 11 is disposed within the first groove 12.

The third sub-signal line 1003 is in the same layer as the second electrode 6. The third sub-signal line 1003 contacts the second sub-signal line 1002 on one sides of the second sub-signal line 1002 and the second filling portions 11 facing away from the first base substrate 1.

In the array substrate provided in the embodiments of the present disclosure, the first signal line includes a plurality of sub-signal lines provided in a stacked manner and electrically connected, i.e., the first signal line is multilayer routing, which can reduce the resistance and lower the impedance of the first signal line under the condition of reducing the line width of each sub-signal line, and can also be conducive to reducing the size of the peripheral area under the condition of reducing the line width of each sub-signal line, and realizing a narrow bezel display.

In some embodiments, the first sub-signal line is provided on the same layer as the source electrode. Therefore, as shown in FIG. 17, a fifth insulation layer 23 is also included between the first signal line 1001 and the planarization layer 3. The fifth insulation layer 23 includes a fourth through hole 2301 penetrating the thickness of the fifth insulation layer 23. The fourth through holes 2301 are in a one-to-one correspondence with the second through holes 302. The fourth through hole 2301 exposes a portion of the first sub-signal line 1001.

In some embodiments, the second through hole and the fourth through hole are formed in the same patterning process, as shown in FIG. 17, with the side of the planarization layer 3 in the second through hole 302 is located on the same inclined plane as the side of the fifth insulation layer 23 in the fourth through hole 2301. That is, the second through hole 302 and the fourth through hole 2301 form a fifth through hole 32. The second sub-signal line 1002 is electrically connected to the first sub-signal line 1001 via the fifth through hole 32.

It is noted that FIG. 17 shows a cross-sectional view along JJ′ in FIG. 2. In FIG. 2, the first signal line 10 includes portions on the left and right sides of, and above, the display area AA, and also includes portions below the display area AA. In FIG. 2, for example, the first signal line 10 surrounds the display area on three edges of the display area AA, the first signal line 10 extends from the peripheral area NA below the display area AA to the peripheral area NA on the left side of the display area AA, and passes through the peripheral area NA above the display area AA and the peripheral area NA on the right side of the display area AA, and then returns to the peripheral area NA below the display area AA. In specific implementations, as shown in FIG. 18, the orthographic projection of the first signal line 10 on the first base substrate 1 may surround the display area AA.

It should be noted that the number and positions of the fifth through holes can be set according to actual needs.

In some embodiments, as shown in FIG. 17, an orthographic projection of the second filling portion 11 on the first base substrate 1 is within orthographic projections of the second sub-signal line 1002 and the third sub-signal line 1003 on the first base substrate 1.

In some embodiments, as shown in FIG. 17, the surface of the second filling portion 11 facing away from the side of the first base substrate 1 is approximately located in the same plane as the surface of the second sub-signal line 1002 outside the second through hole 302 facing away from the side of the first base substrate 1. That is, the second filling portion 11 fills the first groove 12.

In the array substrate provided in the embodiments of the present disclosure, using the second filling portion to fill the groove formed by the second sub-signal line on the side of the second sub-signal line facing away from the first base substrate can improve the flatness of the film layer, so that the surface of the film layer under the subsequently formed third sub-signal line is planar, and the electrical conductivity of the sub-signal line is further improved.

In specific implementations, the second filling portion and the first filling portion are formed in the same patterning process. That is, a filling portion material layer is formed first, and then the patterning process is performed on the filling portion material layer to form patterns of the first filling portion and the second filling portion.

In the array substrate provided in the embodiments of the present disclosure, the second filling portion is provided in the second through hole, so that while forming the first filling portion, there is no need to remove the filling portion material in the second through hole, which can save the process. Moreover, in the array substrate provided in the embodiments of the present disclosure, the second sub-signal line and the third sub-signal line are electrically connected to the first sub-signal line, so that even if the second filling portion is set, it does not affect electrical connections among multi-layer sub-signal lines.

In some embodiments, as shown in FIG. 17, the orthographic projection of the second filling portion 11 on the first base substrate 1 substantially coincides with the orthographic projection of the second through hole 302 on the first base substrate 1.

In particular embodiments, the first through hole and the second through hole are formed in the same patterning process, the second filling portion and the first filling portion are formed in the same patterning process. When the orthographic projection of the first filling portion on the first base substrate coincides with the orthographic projection of the first through hole on the first base substrate and the orthographic projection of the second filling portion on the first base substrate coincides with the orthographic projection of the second through hole on the first base substrate, the second filling portion and the first filling portion can be formed by using a mask board forming the first through hole and the second through hole, which can save cost.

In some embodiments, as shown in FIG. 17, the second sub-signal line 1002 is in contact with the third sub-signal line 1003 in an area outside the second filling portion 11; and in a direction perpendicular to an extension direction of the first signal line 10 (a first direction X in FIG. 17), the second sub-signal line 1002 and the third sub-signal line 1003 each include portions located on both sides of the second filling portion 11, respectively, and regions on both sides of the second filling portion 11 each have regions where the second sub-signal line 1002 contacts the third sub-signal line 1003.

In some embodiments, as shown in FIG. 17, the orthographic projection of the second sub-signal line 1002 on the first base substrate 1 and the orthographic projection of the third sub-signal line 1003 on the first base substrate 1 are substantially coincident, so that the contact area between the second sub-signal line 1002 and the third sub-signal line 1003 can be increased as much as possible to improve the conductive effect.

In some embodiments, as shown in FIG. 17, the first signal line 10 further includes: a fourth sub-signal line 1004 in the same layer as the third electrode 9.

The array substrate further includes: a fourth sub-signal line 1004, where the fourth sub-signal line 1004 is electrically connected to the third sub-signal line 1003 via a through hole, i.e., a sixth through hole 2401, that penetrates the first protection layer 24.

In some embodiments, as shown in FIG. 17, the orthographic projection of the fourth sub-signal line 1004 on the first base substrate 1, the orthographic projection of the second sub-signal line 1002 on the first base substrate 1, and the orthographic projection of the third sub-signal line 1003 on the first base substrate 1 substantially overlap.

In some embodiments, as shown in FIG. 17, at the fifth through hole 32, the fifth insulation layer 23 has a third opening 2301 exposing the first sub-signal line 1001, and at the sixth through hole 2401, the first protection layer 24 has a fourth opening 24011 exposing the third sub-signal line 1003; the orthographic projection of the third opening 2301 on the first base substrate 1 is within the orthographic projection of the fourth opening 24011 on the first base substrate 1.

In some embodiments, as shown in FIG. 17, in the direction perpendicular to the extension direction of the first signal line 10 (the first direction X in FIG. 17), a width h11 of the contact area of the second sub-signal line 1002 and the third sub-signal line 1003 is greater than a width h12 of the third opening 2301, and a width h13 of the fourth opening 24011 is greater than a width h12 of the third opening 2301.

In the related art, the first signal line is also a double-layer wiring including a fourth sub-signal line and a sub-signal line below the planarization layer. The fourth sub-signal line and the sub-signal line are electrically connected via a through hole of an insulation film layer between the fourth sub-signal line and the sub-signal line, but the insulation film layer includes at least a first protection layer and a planarization layer, and due to the thickness of the planarization layer being thicker, the thickness of the first protection layer together with the planarization layer is even thicker, the greater the thickness of the film layer between the sub-signal lines of the double-layer wiring is, the more likely it is to cause the sub-signal lines to lap and break. Moreover, the through hole of the first protection layer and the through hole of the planarization layer are not formed in the same patterning process, and the through hole of the planarization layer is formed first, and then the first protection layer is formed, and the through hole of the first protection layer is formed inside the through hole of the planarization layer, i.e., the through hole of the first protection layer is smaller than the through hole of the planarization layer, which results in the area in which the fourth sub-signal line is electrically connected to the sub-signal line below the planarization layer being reduced, and reduces the performance of the electrical connection between the fourth sub-signal line and the sub-signal line.

In the array substrate provided in the embodiments of the present disclosure, the first signal line includes a greater number of sub-signal lines, so that the fourth sub-signal line is electrically connected to the first sub-signal line by lapping between the second sub-signal line and the first sub-signal line, which can avoid lap breakage caused by a greater thickness of the film layer between the electrically connected sub-signal lines. In the case where the size of the fifth through hole formed by the second through hole and the fourth through hole remains unchanged, the lap area of the second sub-signal line and the first sub-signal line is larger than the lap area of the lap connection between the fourth sub-signal line and the first sub-signal line in the related art, which is conducive to improving the performance of the electrical connection between the sub-signal lines. Moreover, the third sub-signal line and the second sub-signal line have a lap area on both sides of the second filling portion, and the lap area of the third sub-signal line and the second sub-signal line is larger, which can further improve the performance of the electrical connection. In addition, the size of the fourth opening, i.e., the size of the electrical connection between the fourth sub-signal line and the third sub-signal line, is larger than the size of the third opening, and the area of the electrical connection between the fourth sub-signal line and the third sub-signal line is larger. That is, compared to the related art, in the case where the electrical connection is realized via the through hole of the first protection layer, the area of the electrical connection between the two adjacent layers of sub-signal lines is increased, thereby improving the performance of the electrical connection between the sub-signal lines in the first signal line, and improving signal transmission capability of the first signal line. Moreover, even if the second filling portion, the third sub-signal line, and the second sub-signal line are added, the second filling portion is provided on the same layer as the first filling portion, the second sub-signal line is provided on the same layer as the first electrode, and the third sub-signal line is provided on the same layer as the second electrode, the structure of the first signal line of the embodiments of the present disclosure can be fabricated by only changing the pattern of the mask board of the patterning process of each film layer without increasing the process of fabricating the array substrate, avoiding excessive increase in cost.

In some embodiments, at the fifth through hole, an orthographic projection of a symmetry axis of the second filling portion parallel to an extension direction of the first signal line on the first base substrate, an orthographic projection of a symmetry axis of the first sub-signal line parallel to the extension direction of the first signal line on the first base substrate, an orthographic projection of a symmetry axis of the second sub-signal line parallel to the extension direction of the first signal line on the first base substrate, an orthographic projection of a symmetry axis of the third sub-signal line parallel to the extension direction of the first signal line on the first base substrate, and an orthographic projection of a symmetry axis of the fourth sub-signal line parallel to the extension direction of the first signal line on the first base substrate substantially coincide.

In some embodiments, as shown in FIG. 2, the peripheral area NA includes: a first bonding area 13 in the second direction Y on one side of the display area AA.

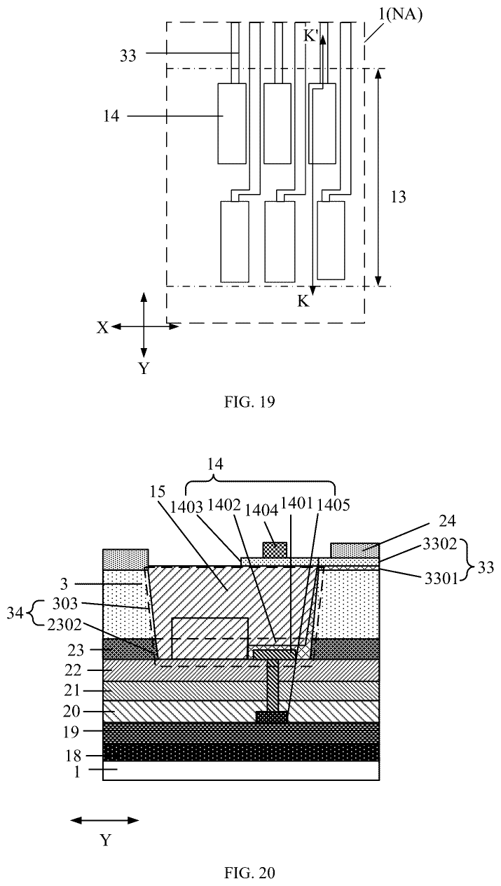

As shown in FIG. 19, the array substrate further includes: a plurality of bonding electrodes 14 in the first bonding area 13, and a plurality of connecting leads 33 extending from the first bonding area 13 to the side of the display area (not shown).

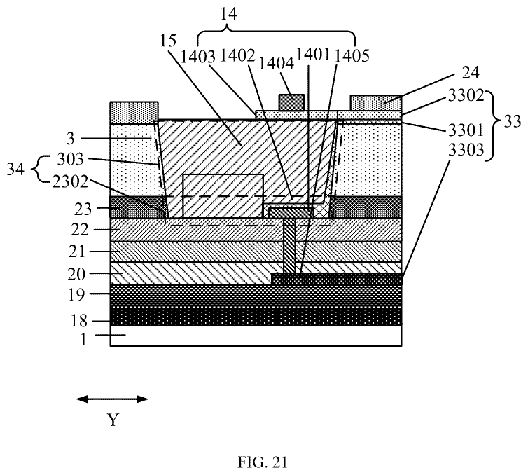

As shown in FIGS. 20 to 23, the planarization layer 3 further includes a third through hole 303, and an orthographic projection of the bonding electrode 14 on the first base substrate 1 is within an orthographic projection of the third through hole 303 on the first base substrate 1.

It is noted that only a portion of the first bonding area 13 is shown in FIG. 19, and FIGS. 20 to 23 are all cross-sectional views along KK′ in FIG. 19.

It should be noted that the plurality of connecting leads include, for example, a plurality of first connecting leads, a plurality of second connecting leads, a plurality of third connecting leads. The plurality of bonding electrodes include, for example, a first bonding electrode(s) electrically connected to a plurality of scan lines via the first connecting lead(s), a second bonding electrode(s) electrically connected to a plurality of second signal lines via the second connecting lead(s), and a third bonding electrode(s) electrically connected to a first signal line(s) via the third connecting lead(s). When the array substrate is applied to the liquid crystal display panel, the array substrate is bound to a driver unit in the first bonding area, so that the driver unit provides corresponding signals to the scan lines, the second signal lines, and the first signal lines via the bonding electrodes. The driver unit includes, for example, a driving chip, a circuit board, and other components.

In some embodiments, as shown in FIGS. 20 to 23, the bonding electrode 14 includes at least: a first sub-electrode 1401, a fourth sub-electrode 1404, and a fifth sub-electrode 1405.

The first sub-electrode 1401 is on a side of the planarization layer 3 facing the first base substrate 1, and the first sub-electrode 1401 is on the same layer as the source electrode (not shown).

The fourth sub-electrode 1404 is provided in the same layer as the third electrode (not shown); and the fourth sub-electrode 1404 is the uppermost sub-electrode in the bonding electrode 14.

The fifth sub-electrode 1405 is on the side of the first sub-electrode 1401 facing the first base substrate 1, and the fifth sub-electrode 1405 is in the same layer as the second light-shielding pattern (not shown) and is electrically connected to the fourth sub-electrode 1404; and the first sub-electrode 1401 is electrically connected to the fifth sub-electrode 1405 via a through hole(s) penetrating the fourth insulation layer 22, the third insulation layer 21, and the second insulation layer 20.

In particular embodiments, the driver unit is electrically connected to the fourth sub-electrode to realize binding of the driver unit to the bonding electrode.

In some embodiments, as shown in FIGS. 20 to 23, the fifth insulation layer 23 further includes a sixth through hole 2302, and the third through hole 303 is in a one-to-one correspondence with the sixth through hole 2302 and is formed in the same patterning process as the sixth through hole 2302, i.e., the third through hole 303 and the sixth through hole 2302 form a complete seventh through hole 34; the seventh through hole 34 exposes the first sub-electrode 1401.

In the array substrate provided in the embodiments of the present disclosure, the third through hole is provided in the planarization layer, and the sixth through hole is provided in the fifth insulation layer, so that electrical connection between at least some of the sub-electrodes in the bonding electrodes can be achieved at the third through hole and the sixth through hole.

In some embodiments, as shown in FIG. 20, the bonding electrode 14 further includes: a second sub-electrode 1402, and a third sub-electrode 1403.

The second sub-electrode 1402 is disposed in the same layer as the first electrode 4 and is electrically connected to the first sub-electrode 1401.

The third sub-electrode 1403 is disposed in the same layer as the second electrode 6 and is electrically connected to the second sub-electrode 1402.

The array substrate further includes: a third filling portion 15 between the second sub-electrode 1402 and the third sub-electrode 1403 in the third through hole 303.

The fourth sub-electrode 1404 is in contact with the third sub-electrode 1403 on the side of the third sub-electrode 1403 facing away from the first base substrate 1.

In some embodiments, the second sub-electrode 1402 is lapped to the first sub-electrode 1401 within the seventh through hole 34, as shown in FIG. 20.

In some embodiments, as shown in FIG. 20, the connecting lead 33 includes: a first sub-lead 3301 in the same layer as the second sub-electrode 1402 and integrally connected with the second sub-electrode 1402, and a second sub-lead 3302 in the same layer as the third sub-electrode 1403 and integrally connected with the third sub-electrode 1403; in the region outside the third filling portion 15, the first sub-lead 3301 is lapped with the second sub-lead 3302, thereby realizing an electrical connection between the second sub-electrode 1402 and the third sub-electrode 1403, thereby realizing an electrical connection between various sub-electrodes in the bonding electrode 14.

It should be noted that the third filling portion is provided in the same layer as the first filling portion and the second filling portion, for example, all the first filling portion, the second filling portion and the third filling portion are formed in a single patterning process, i.e., a filling layer that covers the entire surface of the planarization layer and fills the various through holes in the planarization layer is formed first, and then a patterning process is performed to remove the areas that do not need to be provided with the filling portion. In some embodiments, as shown in FIG. 20, an orthographic projection of the third filling portion 15 on the first base substrate 1 coincides with the orthographic projection of the third through hole 303 on the first base substrate 1. In this way, when the orthographic projection of the first filling portion on the first base substrate coincides the orthographic projection of the first through hole on the first base substrate and the orthographic projection of the second filling portion on the first base substrate coincides the orthographic projection of the second through hole on the first base substrate, the third filling portion, the second filling portion, and the first filling portion can be formed by using the mask board that forms the first through hole, the second through hole, and the third through hole. Moreover, the bonding electrodes in the region of the third through hole include electrically connected second sub-electrodes and third sub-electrodes, so that the electrical connection between various sub-electrodes in the bonding electrodes can be realized without removing the third filling portion, and since the second sub-electrode is provided in the same layer as the first electrode and the third sub-electrode is provided in the same layer as the second electrode, the array substrate can be fabricated without adding a mask board, which can save cost.

In some embodiments, as shown in FIG. 21, the connecting lead 33 further includes: a third sub-lead 3303, which is set in the same layer and integrally connected with the fifth sub-electrode 1405.

In some embodiments, orthographic projections of all the plurality of bonding electrodes on the first base substrate are within an orthographic projection of the same third through hole on the first base substrate. That is, in the first bonding area, third through holes corresponding to the plurality of bonding electrodes are formed in the planarization layer. Correspondingly, sixth through holes corresponding to the plurality of bonding electrodes are formed in the fifth insulation layer, and the array substrate includes a third filling portion.

In some embodiments, an orthographic projection of the seventh through hole on the first base substrate is substantially coincident with the first bonding area. That is, all of the planarization layer and the fifth insulation layer in the first bonding area are removed. Accordingly, an orthographic projection of the third through hole on the first base substrate is substantially coincident with the first bonding area. In the array substrate provided in the embodiments of the present disclosure, all of the planarization layer and the fifth insulation layer in the first bonding area are removed, i.e., the area of the seventh through hole is larger, so that when the material coated with the filling layer forms the filling layer, it is beneficial for the material to level out at the seventh through hole to avoid the material buildup and to improve the flatness of the array substrate.

In some embodiments, as shown in FIG. 20, the first protection layer 24 in the first bonding area is also completely removed, and the fourth sub-electrode 1404 is in direct contact with the third sub-electrode 1403.

It is noted that, as shown in FIG. 19, the plurality of bonding electrodes 14 are not disposed in the same row but are arranged in a plurality of rows, and a portion of the connecting leads 33 passes through the region between two adjacent bonding electrodes 14. If a third filling portion is provided in the region corresponding to the third through hole and the third through hole corresponds to the plurality of bonding electrodes, for the structure as shown in FIG. 20, the electrical connection between the plurality of sub-electrodes in the bonding electrodes 14 can only be realized by lapping the first sub-lead 3301 to the second sub-lead 3302 outside of the third filling portion 15, and the distance between adjacent connecting leads is usually small, if at least one of the second sub-lead and the first sub-lead undergoes an alignment deviation, a short-circuit may occur when subsequently binding with the driver unit.

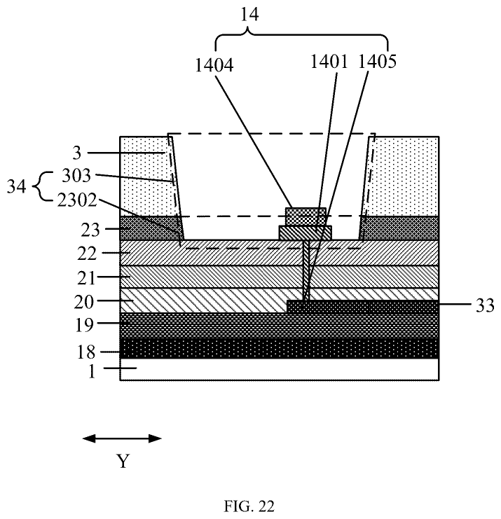

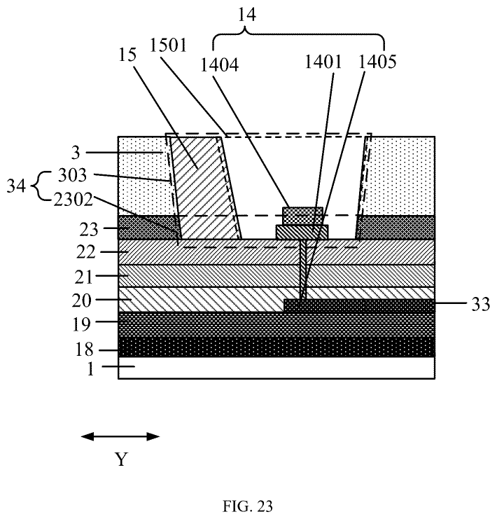

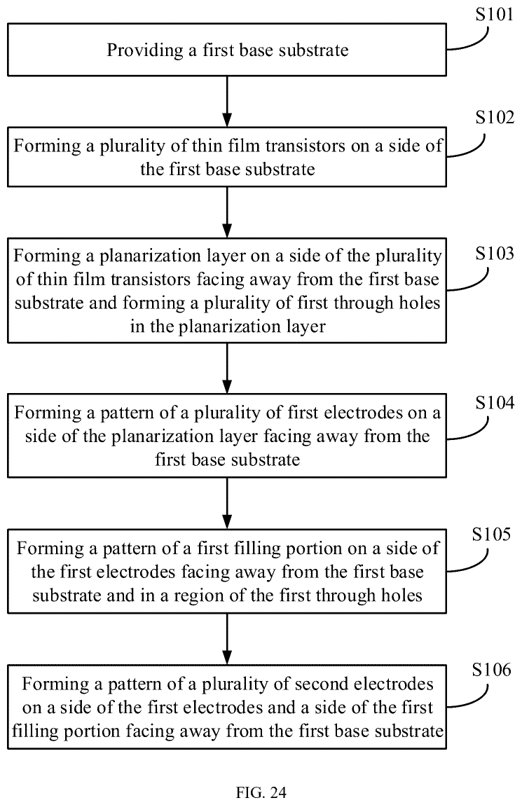

In some embodiments, as shown in FIGS. 22 and 23, a distance from a surface of the side of the bonding electrode 14 facing away from the first base substrate 1 to the first base substrate 1 is smaller than a distance from a surface of the side of the planarization layer 3 facing away from the first base substrate 1 to the first base substrate 1, and a surface of the side of the bonding electrode 14 facing away from the first base substrate 1 is not covered. That is, the uppermost sub-electrode of the bonding electrode 14 is located within the third through hole 303.

In some embodiments, as shown in FIGS. 22 and 23, the fourth sub-electrode 1404 is lapped to the first sub-electrode 1401 within the seventh through hole 34.

In the array substrate provided in the embodiments of the present disclosure, the fourth sub-electrode is lapped to the first sub-electrode directly at the seventh through hole, and the area between the fourth sub-electrode and the first sub-electrode is not provided with the third filling portion, so that it is not necessary to electrically connect the fourth sub-electrode to the first sub-electrode by setting sub-electrodes in the same layer as the first electrode and sub-electrodes in the same layer as the second electrode, and the problem of short-circuiting due to the small distance between the adjacent connecting leads in the event of an alignment deviation can be avoided.

In some embodiments, as shown in FIGS. 22 and 23, the bonding electrode 14 includes only a first sub-electrode 1401, a fourth sub-electrode 1404, and a fifth sub-electrode 1405. The first sub-electrode 1401 is electrically connected to the fifth sub-electrode 1405 via a through hole(s) penetrating the fourth insulation layer 22, the third insulation layer 21, and the second insulation layer 20; at the seventh through hole 34, the first protection layer is removed completely, the first sub-electrode 1401 is directly lapped to the fourth sub-electrode 1404.

In some embodiments, as shown in FIG. 22, the third filling portion is not included in the region corresponding to the third through hole 303. That is, after forming the filling layer, the filling layer at the seventh through hole is removed entirely.

In the array substrate provided in the embodiments of the present disclosure, the third filling portion is not provided at the third through hole in the first bonding area, so that there is no need to electrically connect the fourth sub-electrode to the first sub-electrode by providing a sub-electrode(s) in the same layer as the first electrode and a sub-electrode(s) in the same layer as the second electrode, and the problem of short-circuiting due to the small distance between the adjacent connecting leads in the event of an alignment deviation can be avoided.

Alternatively, in some embodiments, as shown in FIG. 23, the third filling portion 15 is included in the region corresponding to the third through hole 303, and the orthographic projection of the third filling portion 15 on the first base substrate 1 does not overlap with the orthographic projection of the surface of the side of the bonding electrode 14 facing away from the first base substrate 1 on the first base substrate 1, i.e., the orthographic projection of the third filling portion 15 on the first base substrate 1 does not overlap with the orthographic projection of the fourth sub-electrode 1404 on the first base substrate 1.

That is, a portion of the region of the filling layer is removed at the seventh through hole such that the third filling portion does not cover the lapping portion of the fourth sub-electrode and the first sub-electrode.

In some embodiments, as shown in FIG. 23, the third filling portion 15 has a plurality of first removal areas 1501, the first removal areas 1501 being in a one-to-one correspondence with the bonding electrodes 14, and the orthographic projection of the fourth sub-electrode 1404 on the first base substrate 1 is within the orthographic projection of the first removal areas 1501 on the first base substrate 1.

In some embodiments, as shown in FIGS. 22 and 23, the orthographic projections of the plurality of bonding electrodes 14 on the first base substrate 1 all are within the orthographic projection of the same third through hole 303 on the first base substrate 1. That is, the third through hole 303 included in the planarization layer 3 corresponds to the plurality of bonding electrodes 14. A sixth through hole 2302 included in the corresponding fifth insulation layer 23 corresponds to the plurality of bonding electrodes 14.

In some embodiments, an orthographic projection of the seventh through hole on the first base substrate is substantially coincident with the first bonding area. That is, all of the planarization layer and the fifth insulation layer in the first bonding area are removed. Accordingly, the orthographic projection of the third through hole on the first base substrate substantially coincides with the first bonding area.

It should be noted that a material that can be patterned by an exposure development process is usually used as the material of each filling portion. The planarization layer and the fifth insulation layer of the first bonding area are all removed, i.e., the area of the seventh through hole is larger, so that when the material coated with the first filling portion forms a filling layer, it is conducive for the material to be flattened at the seventh through hole to avoid the material to be piled up, so as to avoid the problem of the poor homogeneity of the thickness of the filling layer leading to the existence of a residue at the seventh through hole, and to avoid the bonding electrode to be covered.

In some embodiments, as shown in FIGS. 22 and 23, the connecting lead 33 is provided in the same layer as the fifth sub-electrode 1405 and integrally connected with the fifth sub-electrode 1405.

Based on the same inventive concept, embodiments of the present disclosure further provide a method of preparing an array substrate, as shown in FIG. 24, including the following steps.

S101, providing a first base substrate.

S102, forming a plurality of thin film transistors on a side of the first base substrate; where the thin film transistor includes: a gate electrode, a source electrode, and a drain electrode.

S103, forming a planarization layer on a side of the plurality of thin film transistors facing away from the first base substrate and forming a plurality of first through holes in the planarization layer; where the first through holes are in a one-to-one correspondence with the thin film transistors, and the first through hole exposes at least a partial region of a surface of the drain electrode facing away from the side of the first base substrate.

S104, forming a pattern of a plurality of first electrodes on a side of the planarization layer facing away from the first base substrate; where the first electrodes are connected to the drain electrodes through the first through holes.

S105, forming a pattern of a first filling portion on a side of the first electrodes facing away from the first base substrate and in a region of the first through holes.

S106, forming a pattern of a plurality of second electrodes on a side of the first electrodes and a side of the first filling portion facing away from the first base substrate; where the second electrodes are in one-to-one contact with the first electrodes outside the first through holes.

In the method of preparing the array substrate provided in the embodiments of the present disclosure, the first filling portion is formed at the first through hole and on the side of the first electrode facing away from the drain electrode to fill the first through hole, which can improve the flatness of the region of the array substrate at the first through hole. When the array substrate is applied to a liquid crystal display panel, it can avoid that the existence of a groove region at the edge of a spacer at the first through hole causes liquid crystal disorder and a light leakage risk region, so that a light-shielding pattern does not need to cover the light leakage risk region, and the size of the light-shielding pattern can be reduced, thereby increasing the aperture ratio of the sub-pixel. In particular, for a display product of high pixels per inch, even if the size of the sub-pixel is small, the aperture ratio of the sub-pixel is not lost because the light leakage risk region does not need to be blocked, i.e., the array substrate provided by the embodiments of the present disclosure can be applied to a display product of high pixels per inch. Moreover, in the embodiments of the present disclosure, the array substrate further includes a second electrode in contact with the first electrode outside the first through hole on the side of the first electrode facing away from the first base substrate, that is, the second electrode is electrically connected to the drain electrode through the first electrode. When the array substrate is applied to a liquid crystal display panel, the light effect of the liquid crystal display panel is determined by the second electrode, and the size of the second electrode does not need to avoid the first through hole, which is favorable for improving the light effect by increasing the size of the second electrode.

In some embodiments, before forming the plurality of thin film transistors on the side of the first base substrate, the method further includes:
sequentially forming a buffer layer, a first insulation layer, a plurality of second light-shielding patterns, and a pattern of second insulation layers on the side of the first base substrate;
forming the plurality of thin film transistors on the side of the first base substrate, further including:
sequentially forming the pattern of the plurality of active layers, the third insulation layer, the pattern of the plurality of gate electrodes, the fourth insulation layer, the pattern of the plurality of source electrodes, the fifth insulation layer, and the pattern of the plurality of drain electrodes on the side of the second insulation layer facing away from the second light-shielding pattern.

In some embodiments, after forming the plurality of thin film transistors on the side of the first base substrate, the method further includes:
forming a pattern of color resists on the side of the fifth insulation layer facing away from the source electrodes and in an area outside the drain electrodes.

In some embodiments, after forming the pattern of the plurality of second electrodes on the side of the first electrode facing away from the first base substrate and the side of the first filling portion facing away from the first base substrate, the method further includes:
sequentially forming a first protection layer, a third light-shielding pattern, and a pattern of third electrodes on the side of the second electrodes facing away from the first electrodes.

In some embodiments, forming the pattern of the first filling portion on the side of the first electrode facing away from the first base substrate and in the region of the first through hole, further includes:
forming a filling layer;
performing a patterning process on the filling layer to form the pattern of the first filling portion in the region of the first through hole.

In particular embodiments, performing a patterning process on the filling layer to form the pattern of the first filling portion in the region of the first through hole, further includes:
forming the pattern of the first filling portion using an exposure and development process.

In some embodiments, the first base substrate includes a display area and a peripheral area surrounding the display area;
before forming the planarization layer, further including:
forming a first sub-signal line of the first signal line;
while forming the plurality of first through holes, further including:
forming a plurality of second through holes penetrating a thickness of the planarization layer in the planarization layer;
while forming a pattern of a plurality of first electrodes, further including:
forming a pattern of a second sub-signal line of the first signal line; the second sub-signal line being electrically connected to the first sub-signal line through the second through holes;
performing a patterning process for the filling layer, while forming a pattern of a first filling portion in an area of the first through hole, further including:
forming a pattern of a second filling portion in the region of the second through hole;
while forming a pattern of a plurality of second electrodes, further including:
forming a pattern of a third sub-signal line of the first signal line on a side of the second filling portion facing away from the first base substrate.

In some embodiments, forming the first sub-signal line of the first signal line, further includes:
forming the pattern of the first sub-signal line while forming the pattern of the source electrode.

In some embodiments, while forming the third electrode, the method further includes:
forming the pattern of the fourth sub-signal line; the fourth sub-signal line being electrically connected to the third sub-signal line.

In some embodiments, the first base substrate includes a display area and a peripheral area surrounding the display area; the peripheral area includes: a first bounding area disposed in the second direction on a side of the display area;
before forming the planarization layer, further including:
forming a first sub-electrode of the bonding electrode;
while forming the plurality of first through holes, further including:
forming a third through hole exposing the first bonding area at the planarization layer;
while forming a pattern of the plurality of first electrodes, further including:
forming a pattern of a second sub-electrode of the bonding electrodes; the second sub-electrode being electrically connected to the first sub-electrode through the third through hole;
performing a patterning process on the filling layer, while forming a pattern of the first filling portion in an area of the first through hole, further including:
forming a pattern of a third filling portion in an area of a third through hole;
while forming a pattern of a plurality of second electrodes, further including:
forming a pattern of a third sub-electrode of the bonding electrodes on a side of the third filling portion facing away from the first base substrate.

In some embodiments, while forming the second sub-electrode, further including:
forming a pattern of a first sub-lead of a connecting lead electrically connected to the second sub-electrode;
while forming the third sub-electrode, further including:
forming a pattern of a second sub-lead of a connecting lead electrically connected to the third sub-electrode; the first sub-lead being in contact with the second sub-lead.

In some embodiments, while forming the second light-shielding pattern, further including:
forming a pattern of a fifth sub-electrode of the bonding electrode.

In some embodiments, while forming the fifth sub-electrode, the method further includes:
forming a pattern of a third sub-lead of a connecting lead electrically connected to the fifth sub-electrode.

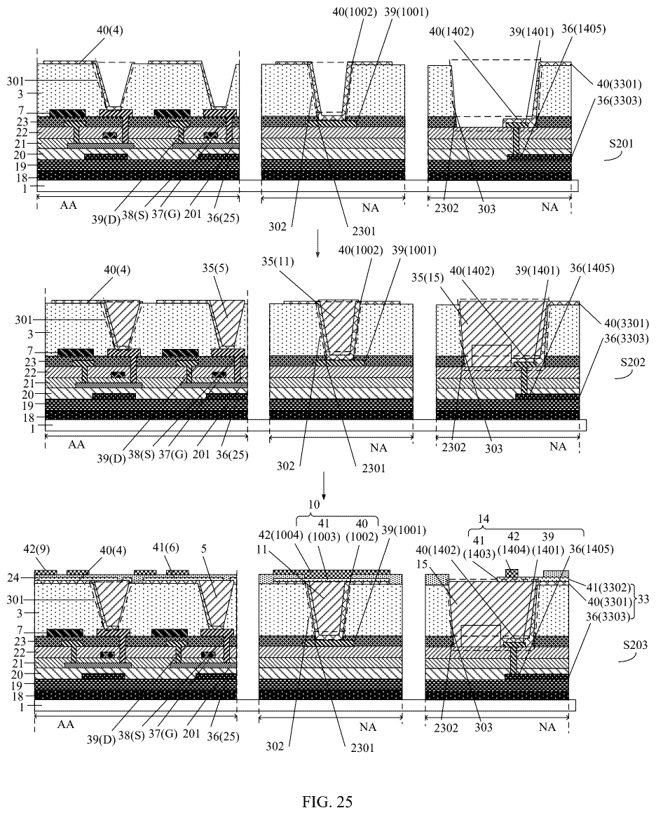

Next, for example, in the preparation method of the array substrate provided by embodiments of the present disclosure, the array substrate includes a first filling portion, a second filling portion, a third filling portion; and the bonding electrode includes a first sub-electrode, a second sub-electrode, a third sub-electrode, a fourth sub-electrode, and a fifth sub-electrode. As shown in FIG. 25, the preparation method of the array substrate includes the following steps.

S201, sequentially forming on a side of a first base substrate 11 a buffer layer 18, a first insulation layer 19, a pattern of a first conductive layer 36, a second insulation layer 20, a pattern of an active layer 201, a third insulation layer 21, a pattern of a second conductive layer 37, a fourth insulation layer 22, a pattern of a third conductive layer 38, a fifth insulation layer 23, a pattern of a fourth conductive layer 39, a pattern of a color resist 7, and a planarization layer 3, and performing a patterning process to form a first through hole 301, a second through hole 302, and a third through hole 303 in a planarization layer 3, while forming a fourth through hole 2301 corresponding to the second through hole 302 and a sixth through hole 2302 corresponding to the third through hole 303 in the fifth insulation layer 23; and thereafter forming a pattern of the fourth conductive layer 39.

Wherein the first conductive layer 36 includes: a second light-shielding pattern 25, a fifth sub-electrode 1405, and a third sub-lead 3303; the second conductive layer 37 includes: a gate electrode G; and the third conductive layer 38 includes: a source electrode S, a first sub-signal line 1001, and a first sub-electrode 1401.

Wherein the fourth conductive layer 39 includes: a first electrode 4, a second sub-signal line 1002, a second sub-electrode 1402, and a first sub-lead 3301.

S202, forming the filling layer 35, and performing a patterning process on the filling layer to form the first filling portion 5, the second filling portion 11, and the third filling portion 15.

Wherein the patterning process performed on the filling layer includes, for example, exposure, and developing.

S203, sequentially forming a pattern of the fifth conductive layer 40, a pattern of the first protection layer 24, a pattern of a third light-shielding pattern (not shown), and a pattern of the sixth conductive layer 41; wherein the fifth conductive layer 40 includes: a second electrode 6, a third sub-signal line 1003, a third sub-electrode 1403, and a second sub-lead 3302; the sixth conductive layer 41 includes: a third electrode 9, a fourth sub-signal line 1004, and a fourth sub-electrode 1404.

Alternatively, in some embodiments, the first base substrate includes a display area and a peripheral area that surrounds the display area; the peripheral area includes: a first bounding area that is disposed on one side of the display area in the second direction.

While forming a plurality of first through holes, the method further includes:
forming a third through hole in the planarization layer; an orthographic projection of the bonding electrode on the first base substrate is within an orthographic projection of the third through hole on the first base substrate;
while performing a patterning process on the filling layer to form a pattern of the first filling portion in the region of the first through hole, further including:
removing the filling layer at the third through hole.

In some embodiments, after removing the filling layer at the third through hole, the method further includes:
detecting whether the filling layer remains at the third through hole, and if so, again performing an exposure and development process on the filling layer remaining at the third through hole to remove the residual filling layer.

Next, the array substrate includes a first filling portion, a second filling portion and the bonding electrode includes a first sub-electrode, a fourth sub-electrode, and a fifth sub-electrode, for example, in the preparation method of the array substrate provided by the embodiments of the present disclosure. The preparation method of the array substrate includes the following steps.

S301, sequentially forming a buffer layer, a first insulation layer, a pattern of the first conductive layer, a second insulation layer, a pattern of the active layer, a third insulation layer, a pattern of the second conductive layer, a fourth insulation layer, a pattern of the third conductive layer, a fifth insulation layer, a pattern of the fourth conductive layer, a pattern of the color resist, and a planarization layer on one side of the first base substrate, and performing a patterning process to form a first through hole, a second through hole, and a third through hole in the planarization layer, while forming a fourth through hole corresponding to the second through hole and a sixth through hole corresponding to the third through hole in the fifth insulation layer; and then forming the pattern of the fourth conductive layer.

Wherein the first conductive layer includes: a second light-shielding pattern, a fifth sub-electrode, and a connecting lead; the second conductive layer includes: a gate electrode; and the third conductive layer includes: a source electrode, a first sub-signal line, and a first sub-electrode.

Wherein the fourth conductive layer includes: a first electrode, and a second sub-signal line.

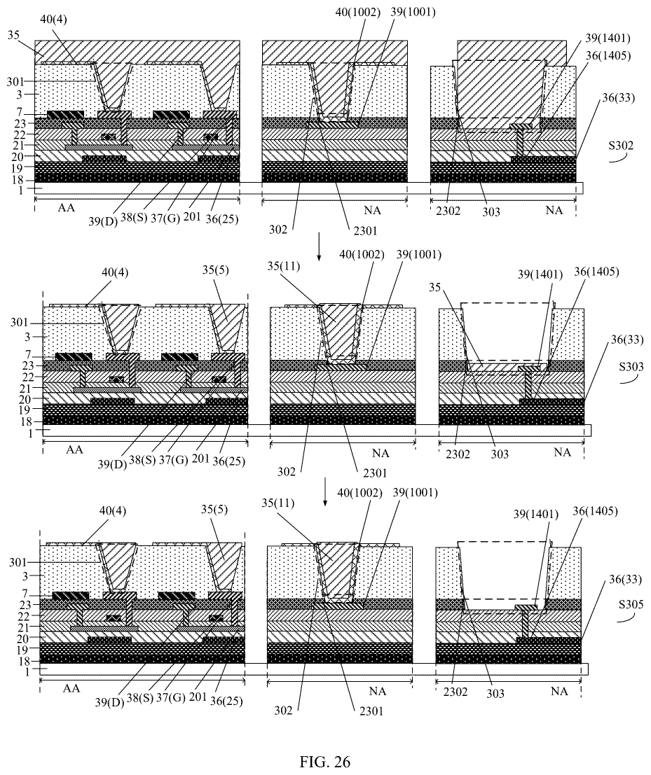

S302, a filling layer 35 is formed as shown in FIG. 26.

S303, the patterning process performed on the filling layer 35 forms a first filling portion 5 at the first through hole 301, a second filling portion 11 at the second through hole 302, and the filling layer 35 at the third through hole 303 is removed.

Wherein the patterning process performed on the filling layer includes, for example, exposure, developing.

S304, detecting whether the filling layer remains at the third through hole; if so, performing step S305, otherwise performing step S306.

S305, as shown in FIG. 26, again performing an exposure and developing process to remove the filling layer 35 for all filling layers 35 at the third through hole 303.

S306, sequentially forming a pattern of a fifth conductive layer, a first protection layer, a third light-shielding pattern, and a pattern of a sixth conductive layer; wherein the fifth conductive layer includes: a second electrode, a third sub-signal line; and the sixth conductive layer includes: a third electrode, a fourth sub-signal line, and a fourth sub-electrode.

In some embodiments, the first base substrate includes a display area and a peripheral area surrounding the display area; the peripheral area includes: a first bounding area disposed in the second direction on a side of the display area.

While forming the plurality of first through holes, the method further includes:
forming a third through hole in the planarization layer; where an orthographic projection of the bonding electrode on the first base substrate is within an orthographic projection of the third through hole on the first base substrate.

While performing a patterning process on the filling layer to form a pattern of the first filling portion in the region of the first through hole, the method further includes:
removing a portion of the filling layer at the third through hole to form a third filling portion and a plurality of first removal areas; where the orthographic projection of the third filling portion on the first base substrate and the orthographic projection of the surface of the side of the bonding electrode facing away from the first base substrate on the first base substrate do not overlap with each other; and the orthographic projection of the surface of the side of the bonding electrode facing away from the first base substrate on the first base substrate is within the orthographic projection of the first removal area on the first base substrate.

Next, in a preparation method of the array substrate provided by embodiments of the present disclosure, for example, the array substrate includes a first filling portion, a second filling portion, a third filling portion, a first removal area, and the bonding electrode includes a first sub-electrode, a fourth sub-electrode, and a fifth sub-electrode. The preparation method of the array substrate includes the following steps.

S401, forming a buffer layer, a first insulation layer, a pattern of the first conductive layer, a second insulation layer, a pattern of the active layer, a third insulation layer, a pattern of the second conductive layer, a fourth insulation layer, a pattern of the third conductive layer, a fifth insulation layer, a pattern of the fourth conductive layer, a pattern of the color resist, and a planarization layer in sequence on one side of the first base substrate, and performing a patterning process to form a first through hole, a second through hole and a third through hole in the planarization layer, while forming a fourth through hole corresponding to the second through hole and a sixth through hole corresponding to the third through hole in the fifth insulation layer; and thereafter forming the pattern of the fourth conductive layer.

Wherein the first conductive layer includes: a second light-shielding pattern, a fifth sub-electrode, and a connecting lead; the second conductive layer includes: a gate electrode; and the third conductive layer includes: a source electrode, a first sub-signal line, and a first sub-electrode.

Wherein the fourth conductive layer includes: a first electrode, and a second sub-signal line.

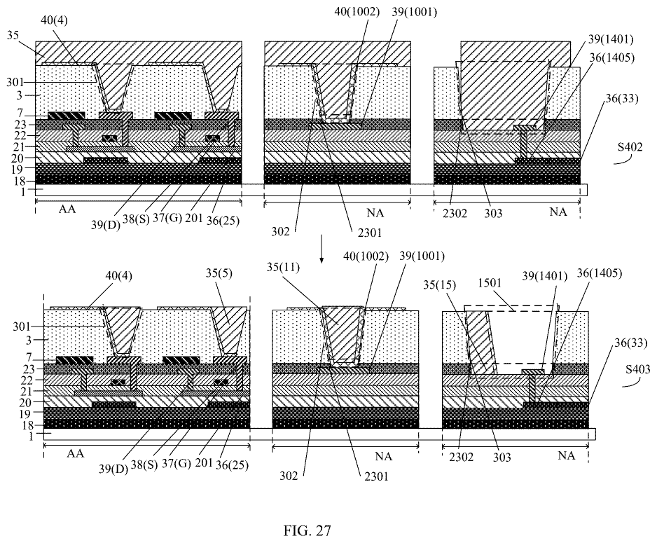

S402, a filling layer 35 is formed as shown in FIG. 27.

S403, as shown in FIG. 27, a patterning process is performed on the filling layer 35 to form a first filling portion 5 at a first through hole 301, a second filling portion 11 at a second through hole 302, and a third filling portion 15 at a third through hole 303, as well as a first removal area 1501.

### Wherein the Patterning Process Performed on the Filling Layer Includes, for Example, exposure and development.

S404, sequentially forming a pattern of the fifth conductive layer, a pattern of the first protection layer, a pattern of the second light-shielding pattern, and a pattern of the sixth conductive layer; wherein the fifth conductive layer includes: a second electrode, a third sub-signal line; and the sixth conductive layer includes: a third electrode, a fourth sub-signal line, and a fourth sub-electrode.

In some embodiments, the first mask plate is used to perform a patterning process for the filling layer. The first mask plate includes a light-transmitting region and a non-light-transmitting region. The pattern of the non-light-transmitting region substantially overlaps with the pattern of the first filling portion, the pattern of the second filling portion, and the pattern of the third filling portion. The exposure of the filling layer using the first mask plate is performed with an exposure process, and all of the light-transmitting regions have the same exposure amount.

Alternatively, in some embodiments, a second mask plate is used to perform a patterning process for the filling layer. The first mask plate includes a first light-transmitting region, a second light-transmitting region, and a non-light-transmitting region. The pattern of the non-light-transmitting region substantially overlaps with the pattern of the first filling portion, the pattern of the second filling portion, and the pattern of the third filling portion. The pattern of the first light-transmitting region substantially overlaps with the pattern of the first removal area. When the exposure process is performed on the filling layer using the second mask plate, the exposure amount of the first light-transmitting region is larger than the exposure amount of the second light-transmitting region, so that it can be ensured that all the filling layers in the first removal area are removed, avoiding that the filling layer shields the first sub-electrode.

It should be noted that, in the preparation method of the above array substrate provided by the embodiments of the present disclosure, the pattern, positional relationship, and the like of each film layer in the array substrate are referred to the embodiments of the above array substrate provided by the embodiments of the present disclosure, and will not be repeated herein.

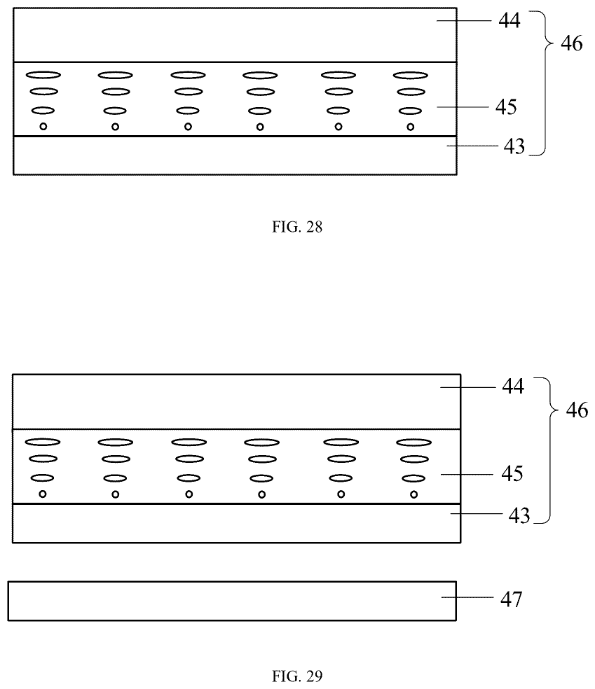

Embodiments of the present disclosure provide a display panel, as shown in FIG. 28, the display panel including:
the array substrate 43 provided by the embodiments of the present disclosure;
an opposing substrate 44, opposite to the array substrate 43;
a liquid crystal layer 45, between the array substrate 43 and the opposing substrate 44.

In some embodiments, the array substrate includes a first light-transmitting region; the opposing substrate includes:
a second base substrate;
a first light-shielding pattern, on a side of the second base substrate facing the liquid crystal layer, and including a plurality of first opening areas; an orthographic projection of the first light-shielding pattern on the first base substrate covers the first light-shielding regions.

In some embodiments, the orthographic projections of the first opening areas on the first base substrate overlap the first light-transmitting regions, and in the display area, the orthographic projection of the first light-shielding pattern on the first base substrate overlaps all the first light-shielding regions and all the second light-shielding regions of the plurality of sub-pixel areas.

In particular embodiments, the array substrate is further provided with a alignment layer on the side of the array substrate close to the liquid crystal layer and on the side of the opposing substrate close to the liquid crystal layer. The side of the array substrate close to the liquid crystal layer and/or the side of the opposing substrate close to the liquid crystal layer is/are also provided with a spacer(s). An orthographic projection of the spacer on the second base substrate is disposed in an orthographic projection of the first light-shielding pattern on the second base substrate.

In the display panel provided in the embodiments of the present disclosure, in the array substrate, the first filling portion is used to fill in the first through hole on a side of the first electrode facing away from the drain electrode, to improve the flatness of the region of the array substrate at the first through hole and to avoid that the existence of a groove region at the edge of a spacer at the first through hole causes liquid crystal disorder and a light leakage risk region, so that a light-shielding pattern does not need to cover the light leakage risk region, and the size of the light-shielding pattern can be reduced, thereby increasing the aperture ratio of the sub-pixel. In particular, for a display product of high pixels per inch, even if the size of the sub-pixel is small, the aperture ratio of the sub-pixel is not lost because the light leakage risk region does not need to be blocked. Moreover, the array substrate further includes a second electrode in contact with the first electrode outside the first through hole on the side of the first electrode facing away from the first base substrate, that is, the second electrode is electrically connected to the drain electrode through the first electrode. When the array substrate is applied to a liquid crystal display panel, the light effect of the liquid crystal display panel is determined by the second electrode, and the size of the second electrode does not need to avoid the first through hole, which is favorable for improving the light effect by increasing the size of the second electrode.

Embodiments of the present disclosure provide a display device, as shown in FIG. 29, the display device includes a display panel 46 provided by embodiments of the present disclosure.

In some embodiments, in the above-described display device provided by embodiments of the present disclosure, as shown in FIG. 29, the display device may also include a backlight module 47 on the light-entry side of the array substrate 43. The backlight module may be a straight-down backlight module or a side-entry backlight module.

In specific implementations, the edge-lit backlight module may include a light bar, stacked reflective sheets, a light guide plate, a diffusion sheet, a prism set, and the like, and the light bar is disposed on one side of the light guide plate in the thickness direction. The direct backlight module may include a matrix light source, a reflective sheet, a diffusion plate, and a brightening film, etc., disposed in a stack manner at the light output side of the matrix light source. The reflective sheet includes a through hole exactly facing each lamp bead in the matrix light source. The lamp beads in the light bar and the lamp beads in the matrix light source may be light-emitting diodes (LEDs), such as miniature light-emitting diodes (Mini LEDs, Micro LEDs, etc.). Sub-millimeter scale or even micron scale miniature light-emitting diodes and organic light-emitting diodes (OLEDs) belong to the self-luminous devices. Like organic light-emitting diodes, they have a series of advantages such as high brightness, ultra-low latency, and large viewing angle. Further, the light emitting of the inorganic light-emitting diode is based on the metal semiconductor which is more stable and has lower resistance, so compared to organic light-emitting diodes whose light emitting is based on organic compounds, the inorganic light-emitting diode has the advantages of lower power consumption, higher resistance to high and low temperatures, and longer service life. When the micro light-emitting diode is used as a backlight source, a more precise dynamic backlight effect can be achieved, which effectively improves the brightness and contrast of the screen while also solving the glare phenomenon caused by the traditional dynamic backlight between the bright and dark areas of the screen, thereby optimizing the visual experience.

The display device provided by the embodiments of the present disclosure is: a cell phone, a tablet computer, a television, a monitor, a laptop computer, a digital photo frame, a navigator, and any other product or component with a display function. Other essential components of the display device are understood by those of ordinary skill in the art, and are not described herein, nor should they be used as a limitation of the present disclosure. The implementation of the display device can be seen in the above embodiments of the array substrates and display panels, and will not be repeated.

In summary, in the array substrate, the preparation method thereof, the display panel, and the display device provided by the embodiments of the present disclosure, the first filling portion is used to fill in the first through hole on a side of the first electrode facing away from the drain electrode, to improve the flatness of the region of the array substrate at the first through hole. When the array substrate is applied to a liquid crystal display panel, it can avoid that the existence of a groove region at the edge of a spacer at the first through hole causes liquid crystal disorder and a light leakage risk region, so that a light-shielding pattern does not need to cover the light leakage risk region, and the size of the light-shielding pattern can be reduced, thereby increasing the aperture ratio of the sub-pixel. In particular, for a display product of high pixels per inch, even if the size of the sub-pixel is small, the aperture ratio of the sub-pixel is not lost because the light leakage risk region does not need to be blocked, i.e., the array substrate provided by the embodiments of the present disclosure can be applied to a display product of high pixels per inch. Moreover, in the embodiments of the present disclosure, the array substrate further includes a second electrode in contact with the first electrode outside the first through hole on the side of the first electrode facing away from the first base substrate, that is, the second electrode is electrically connected to the drain electrode through the first electrode. When the array substrate is applied to a liquid crystal display panel, the light effect of the liquid crystal display panel is determined by the second electrode, and the size of the second electrode does not need to avoid the first through hole, which is favorable for improving the light effect by increasing the size of the second electrode.

Although preferred embodiments of the present disclosure have been described, those skilled in the art may make additional changes and modifications to these embodiments once the basic inventive concepts are known. Therefore, the appended claims are intended to be construed to include the preferred embodiments as well as all changes and modifications that are within the scope of the present disclosure.

Obviously, a person skilled in the art may make various changes and variations to the embodiments of the present disclosure without departing from the spirit and scope of the embodiments of the present disclosure. Thus, if these modifications and variations of the embodiments of the present disclosure are within the scope of the claims of the present disclosure and their technical equivalents, the present disclosure is intended to encompass these modifications and variations as well.

1-34. (canceled)

35. An array substrate, comprising:
a first base substrate;
a plurality of thin film transistors, on a side of the first base substrate; each of the thin film transistors comprising a gate electrode, a source electrode, and a drain electrode;
a planarization layer, disposed on a side of the drain electrode facing away from the first base substrate, and comprising first through holes in a one-to-one correspondence with the plurality of thin film transistors; the first through hole exposing at least some region of a surface of the drain electrode facing away from the first base substrate;
a plurality of first electrodes, on a side of the planarization layer facing away from the first base substrate; the first electrodes being connected to the drain electrodes through the first through holes;
a plurality of first filling portions, at least within the first through holes and on a side of the first electrodes facing away from the first base substrate;
a plurality of second electrodes, on a side of the first electrodes facing away from the first base substrate and a side of the first filling portions facing away from the first base substrate; the second electrodes and the first electrodes being in contact with each other outside of the first through holes.

36. The array substrate according to claim 35, wherein the first base substrate comprises a display area and a peripheral area surrounding the display area;
the display area comprises a plurality of sub-pixel areas arranged in an array along a first direction and a second direction; each of the sub-pixel areas comprises a first light-transmitting region and a first light-shielding region, and the first light-shielding region is on a side of the first light-transmitting region in the second direction;
an orthographic projection of the second electrode on the first base substrate overlaps with the first light-transmitting region;
an orthographic projection of the first through hole on the first base substrate is within the first light-shielding region;
an orthographic projection of the first filling portion on the first base substrate comprises at least a portion within the first light-shielding region.

37. The array substrate according to claim 36, wherein an orthographic projection of the first electrode on the first base substrate overlaps with the first light-transmitting region;
in the first light-transmitting region and in the second direction, a width of the second electrode is greater than a width of the first electrode.

38. The array substrate according to claim 36, wherein the first electrodes and the second electrodes that are in contact with each other are staggered in the second direction.

39. The array substrate according to claim 38, wherein the orthographic projection of the second electrode on the first base substrate overlaps with the first light-shielding region;
wherein, in the second direction, an orthographic projection of a region between two adjacent second electrodes on the first base substrate overlaps with both the first light-transmitting region and the first light-shielding region.

40. The array substrate according to claim 39, wherein the first electrode comprises: a first portion outside of the first through hole and a second portion, and the second portion is located on a side of the first portion in the second direction and is at least partially located within the first through hole;
the second electrode comprises: a third portion outside the first through hole and a fourth portion, and the fourth portion is located on a side of the third portion in the second direction and is at least partially located within the first through hole;
in the second direction, a width of the first portion is smaller than a width of the third portion, and a width of the second portion is greater than a width of the fourth portion.

41. The array substrate according to claim 40, wherein the second portion completely covers the surface of the drain electrode exposed by the first through hole.

42. The array substrate according to claim 40, wherein the second electrode further comprises: a fifth portion on a side of the third portion facing away from the fourth portion in the second direction;
an orthographic projection of the fifth portion on the first base substrate is within the first light-shielding region;
in the second direction, an orthographic projection of a gap between two adjacent second electrodes on the first base substrate is within the orthographic projection of the first filling portion on the first base substrate.

43. The array substrate according to claim 40, wherein a surface of the first filling portion facing away from the first base substrate is substantially on a same plane as a surface of the first portion facing away from the first base substrate.

44. The array substrate according to claim 36, wherein in the first direction, a width of the first electrode is substantially equal to a width of the second electrode;
edges, extending in the second direction, at a same side of the first electrode and the second electrode substantially coincide;
wherein the array substrate further comprises:
a plurality of color resists, in a one-to-one correspondence with the sub-pixel areas, and on a side of the planarization layer close to the first base substrate; wherein an orthographic projection of the color resist on the first base substrate covers at least the first light-transmitting region;
wherein the color resist and the drain electrode are in the same layer;
the orthographic projection of the color resist on the first base substrate does not overlap with an orthographic projection of the drain electrode on the first base substrate, and the orthographic projection of the color resist on the first base substrate does not overlap with the orthographic projection of the first through hole on the first base substrate;
wherein the source electrode is located at a side of the drain electrode facing the first base substrate;
the array substrate further comprises a first interlayer insulation layer between the source electrode and the drain electrode; and
the color resist and the drain electrode are located between the first interlayer insulation layer and the planarization layer.

45. The array substrate according to claim 36, wherein the array substrate further comprises: a first signal line in the peripheral area, and a plurality of second filling portions; the first signal line is electrically connected to a third electrode;
the first signal line comprises: a first sub-signal line, a second sub-signal line, and a third sub-signal line arranged in a stacked manner;
the first sub-signal line is disposed on a side of the planarization layer facing the first base substrate;
the second sub-signal line is in the same layer as the first electrode; the planarization layer further comprises a plurality of second through holes penetrating through a thickness of the planarization layer, the second sub-signal line is electrically connected to the first sub-signal line through the second through hole, the second sub-signal line has a first groove at the second through hole; and the second filling portion is located within the first groove;
the third sub-signal line is in the same layer as the second electrode, the third sub-signal line is in contact with the second sub-signal line on a side of the second sub-signal line and the second filling portion facing away from the first base substrate.

46. The array substrate according to claim 45, wherein an orthographic projection of the second filling portion on the first base substrate is within an orthographic projection of the second sub-signal line on the first base substrate and an orthographic projection of the third sub-signal line on the first base substrate;
wherein the first sub-signal line is in the same layer as the source electrode;
wherein, in the display area, the array substrate further comprises: the third electrode on a side of the second electrode facing away from the first base substrate;
the first signal line further comprises: a fourth sub-signal line in the same layer as the third electrode;
the array substrate further comprises: a first protection layer between the third sub-signal line and the fourth sub-signal line; the fourth sub-signal line is electrically connected to the third sub-signal line via a through hole penetrating through the first protection layer.

47. The array substrate according to claim 36, wherein the peripheral area comprises: a first bonding area on a side of the display area in the second direction;
the array substrate further comprises: a plurality of bonding electrodes in the first bonding area;
the planarization layer further comprises a third through hole, an orthographic projection of the bonding electrode on the first base substrate is within an orthographic projection of the third through hole on the first base substrate.

48. The array substrate according to claim 47, wherein the bonding electrode comprises: a first sub-electrode, a second sub-electrode, a third sub-electrode, and a fourth sub-electrode;
the first sub-electrode is disposed on a side of the planarization layer facing the first base substrate;
the second sub-electrode is in the same layer as the first electrode and is electrically connected to the first sub-electrode;
the third sub-electrode is in the same layer as the second electrode and is electrically connected to the second sub-electrode;
the array substrate further comprises: a third filling portion within the third through hole and between the second sub-electrode and the third sub-electrode;
the fourth sub-electrode is in contact with the third sub-electrode on a side of the third sub-electrode facing away from the first base substrate;
wherein the array substrate comprises a third electrode; the fourth sub-electrode is in the same layer as the third electrode.

49. The array substrate according to claim 47, wherein a distance between a surface of the bonding electrode facing away from the first base substrate and the first base substrate is less than a distance between a surface of the planarization layer facing away from the first base substrate and the first base substrate, and the surface of the bonding electrode facing away from the side of the first base substrate is not covered.

50. The array substrate according to claim 49, wherein the array substrate further comprises: a third filling portion in a part of an area inside the third through hole; an orthographic projection of the third filling portion on the first base substrate does not overlap with an orthographic projection of a surface of the bonding electrode exposed by the third through hole and facing away from the first base substrate on the first base substrate.

51. The array substrate according to claim 47, wherein orthographic projections of the plurality of bonding electrodes on the first base substrate are all within an orthographic projection of the same third through hole on the first base substrate.

52. A preparation method of an array substrate, comprising:
providing a first base substrate;
forming a plurality of thin film transistors on a side of the first base substrate; wherein each of the thin film transistors comprises a gate electrode, a source electrode, and a drain electrode;
forming a planarization layer on a side of the plurality of thin film transistors facing away from the first base substrate and forming a plurality of first through holes in the planarization layer; wherein the first through holes are in a one-to-one correspondence with the thin film transistors, the first through hole exposes at least some region of a surface of the drain electrode facing away from the side of the first base substrate;
forming a pattern of a plurality of first electrodes on a side of the planarization layer facing away from the first base substrate; wherein the first electrodes are connected to the drain electrodes through the first through holes;
forming a pattern of first filling portions on a side of the first electrodes facing away from the first base substrate and in regions of the first through holes;
forming a pattern of a plurality of second electrodes on a side of the first electrodes and a side of the first filling portions facing away from the first base substrate; wherein the second electrodes and the first electrodes are in contact with each other outside the first through holes.

53. A display panel, comprising:
the array substrate according to claim 35;
an opposing substrate, opposite to the array substrate;
a liquid crystal layer, between the array substrate and the opposing substrate;
wherein the array substrate comprises a first light-transmitting region; the opposing substrate comprises:
a second base substrate;
a first light-shielding pattern, comprising a plurality of first openings; wherein an orthographic projection of the first light-shielding pattern on the first base substrate covers the first light-shielding region.

54. A display device, comprising the display panel according to claim 53.
